(19) United States
(12) Patent Application Publication
(10) Pub. No.: US 2025/0143033 A1
(43) Pub. Date: May 1, 2025

(54) CHIP STRUCTURE AND METHOD FOR MANUFACTURING THE SAME, AND DISPLAY APPARATUS

(71) Applicant: BOE TECHNOLOGY GROUP CO., LTD., Beijing (CN)

(72) Inventors: Xiaohu LI, Beijing (CN); Yichi ZHANG, Beijing (CN); Wei LI, Beijing (CN); Zhiqiang JIAO, Beijing (CN); Lu WANG, Beijing (CN)

(73) Assignee: BOE TECHNOLOGY GROUP CO., LTD., Beijing (CN)

(21) Appl. No.: 18/712,703

(22) PCT Filed: Mar. 29, 2023
(86) PCT No.: PCT/CN2023/084756

§ 371 Date: May 23, 2024

(51) Int. Cl. H10H 20/851; H10H 20/01; H10H 20/85

(52) U.S. Cl. CPC H10H 20/851; H10H 20/021; H10H 20/0361; H10H 20/8504

(57) ABSTRACT

A chip structure and a method for manufacturing the same, and a display apparatus. The chip structure includes a chip wafer unit and a color conversion unit disposed on a light exit side of the chip wafer unit. The color conversion unit includes a base substrate; the base substrate includes a body portion and an edge portion surrounding the body portion; the edge portion includes original layers and modified layers alternately arranged along a first direction; and in the edge portion, layers located on outermost two sides in the first direction are both original layers, the first direction being perpendicular to a surface of the base substrate away from the chip wafer unit. A light reflectivity of the original layers and a light reflectivity of the modified layers are different.

### CROSS-REFERENCE TO RELATED APPLICATION

This application is a national phase entry under 35 USC 371 of International Patent Application No. PCT/CN2023/084756, filed on Mar. 29, 2023, which is incorporated herein by reference in its entirety.

### TECHNICAL FIELD

The present disclosure relates to the field of display technologies, and in particular, to a chip structure, a method for manufacturing a chip structure, and a display apparatus.

### BACKGROUND

Micro light-emitting diode (Micro-LED) display devices are a new generation of display technology with the advantages of high brightness, high luminous efficiency, low power consumption, and fast response speed.

### SUMMARY

In an aspect, a chip structure is provided. The chip structure includes: a chip wafer unit and a color conversion unit disposed on a light exit side of the chip wafer unit. The color conversion unit includes a base substrate, the base substrate includes a body portion and an edge portion surrounding the body portion: the edge portion includes original layers and modified layers alternately arranged along a first direction; in the edge portion, layers located on outermost two sides in the first direction are both original layers; and a light reflectivity of the original layers and a light reflectivity of the modified layers are different. The first direction is perpendicular to a surface of the base substrate away from the chip wafer unit.

In some embodiments, the body portion and the original layers have the same light reflectivity.

In some embodiments, the base substrate includes a first surface and a second surface opposite to each other in the first direction, and a plurality of side surfaces connecting the first surface and the second surface; the second surface is closer to the chip wafer unit than the first surface, and the edge portion includes a plurality of sub-portions that are respectively arranged corresponding to the plurality of side surfaces. A number of modified layers included in each of the plurality of sub-portions is the same; or the number of modified layers included in each of the plurality of sub-portions is not necessarily the same.

In some embodiments, at least one sub-portion among the plurality of sub-portions includes N modified layers, N is a positive integer, and N >2. A modified layer farthest from the chip wafer unit is a first modified layer, and a modified layer closest to the chip wafer unit is an Nth modified layer. A distance between the first modified layer and the first surface is greater than a distance between any two adjacent modified layers; and/or, a distance between the Nth modified layer and the second surface is greater than the distance between any two adjacent modified layers.

In some embodiments, the distance between the first modified layer and the first surface is in a range of 15 μm to 35 μm, inclusive; and/or the distance between the Nth modified layer and the second surface is in a range of 15 μm to 35 μm, inclusive.

In some embodiments, the distance between the first modified layer and the first surface is greater than or equal to 20 μm; and/or the distance between the Nth modified layer and the second surface is greater than or equal to 20 μm.

In some embodiments, the color conversion unit further includes: a color filter layer, a defining dam layer and a color conversion layer. The color filter layer is disposed on a side of the base substrate facing the chip wafer unit. The color filter layer includes a black matrix and a plurality of filter portions defined by the black matrix. An orthographic projection of the black matrix on the base substrate being located within a range enclosed by the edge portion. The defining dam layer is disposed on a side of the color filter layer away from the base substrate, and the defining dam layer includes a plurality of opening regions in one-to-one correspondence with the plurality of filter portions. The color conversion layer is arranged in the same layer as the defining dam layer.

In some embodiments, the plurality of opening regions include a first-type opening region and a second-type opening region. The color conversion layer includes a color conversion portion and a filling portion. The color conversion portion includes a quantum dot conversion portion or a fluorescent color conversion portion. The filling portion includes a scattering particle portion or transparent glue. The color conversion portion is arranged in the first-type opening region, and the filling portion is arranged in the second-type opening region.

In some embodiments, the base substrate includes a functional region and a peripheral region surrounding the functional region, an orthographic projection of the chip wafer unit on the base substrate is located in the functional region, the body portion is located at least in the functional region, and the edge portion is located in the peripheral region. The color conversion unit further includes an encapsulation layer covering the color filter layer. A portion, located in the peripheral region, of an orthographic projection of the encapsulation layer on the base substrate overlaps with the edge portion.

In some embodiments, a distance between a border of the black matrix and a side surface of the base substrate is e1, a size of a modified layer in a direction that is parallel to the first surface and perpendicular to the side surface is e2, and e2≤e1.

In some embodiments, the size e2 of the modified layer in the direction that is parallel to the first surface and perpendicular to the side surface is in a range of 5 μm to 10 μm, inclusive.

In some embodiments, the distance e1 between the border of the black matrix and the side surface is in a range of 10 μm to 30 μm, inclusive.

In another aspect, a display apparatus is provided. The display apparatus includes a driving substrate and a plurality of chip structures provided according to any of the above embodiments, and the driving substrate is coupled to the plurality of chip structures.

In yet another aspect, a method for manufacturing a chip structure is provided. The method includes the following steps.

An initial wafer is formed, the initial wafer including a plurality of chip wafer units.

A color conversion substrate is formed; the color conversion substrate includes a base substrate motherboard and a plurality of color conversion structures disposed on the base substrate motherboard, and each color conversion structure and a portion of the base substrate motherboard corresponding thereto constitute a color conversion unit.

The color conversion substrate is coupled to the initial wafer to obtain a coupling structure, and each chip wafer unit is arranged opposite to one color conversion unit.

The laser is sequentially applied to a plurality of focuses inside the base substrate motherboard for cutting. The plurality of focuses are arranged sequentially in a first direction, the first direction being perpendicular to a surface of the base substrate motherboard away from the plurality of color conversion structures; the base substrate motherboard is cut to form a plurality of base substrates, each base substrate includes a body portion and an edge portion surrounding the body portion, the edge portion includes original layers and modified layers alternately arranged along the first direction, and layers located on outermost two sides in the first direction are both original layers.

In some embodiments, in the step of sequentially applying the laser to the plurality of focuses inside the base substrate motherboard for cutting, the base substrate motherboard is cut from a side of the color conversion substrate of the coupling structure away from the initial wafer.

In some embodiments, the base substrate motherboard includes a plurality of cutting lanes, and the laser cuts along the cutting lanes. When the laser cuts each of the cutting lanes, a number of focuses to which the laser is applied is the same or not necessarily the same.

In some embodiments, in the step of sequentially applying the laser to the plurality of focuses inside the base substrate motherboard for cutting, the number of focuses is N, N is a positive integer, and N≥2; a focus farthest from the initial wafer is a first focus, and a focus closest to the initial wafer is an Nth focus; a surface of the base substrate motherboard away from the initial wafer is a first surface, and a surface of the base substrate motherboard close to the initial wafer is a second surface.

A distance between the first focus and the first surface of the base substrate motherboard is greater than or equal to a distance between any two adjacent focuses; and/or, a distance between the Nth focus and the second surface of the base substrate motherboard is greater than or equal to the distance between any two adjacent focuses.

In some embodiments, the distance between the first focus and the first surface of the base substrate motherboard is in a range of 15 μm to 35 μm, inclusive; and/or the distance between the Nth focus and the second surface of the base substrate motherboard is in a range of 15 μm to 35 μm, inclusive.

In some embodiments, a distance between any two adjacent chip structures is in a range of 20 μm to 50 μm, inclusive.

### BRIEF DESCRIPTION OF THE DRAWINGS

In order to describe technical solutions in the present disclosure more clearly, the accompanying drawings to be used in some embodiments of the present disclosure will be introduced briefly. However, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a plan view showing a structure of a display apparatus, in accordance with some embodiments;

FIG. 2 is a sectional structural view taken along the section line GG in FIG. 1;

FIG. 3 is a flow diagram of a manufacturing method for a chip structure, in accordance with some embodiments;

FIG. 4 is a top view showing a structure corresponding to a step S1 of the manufacturing method in FIG. 3;

FIG. 5 is a top view showing a structure corresponding to a step S2 of the manufacturing method in FIG. 3;

FIG. 6 is a top view showing a structure corresponding to a step S3 of the manufacturing method in FIG. 3;

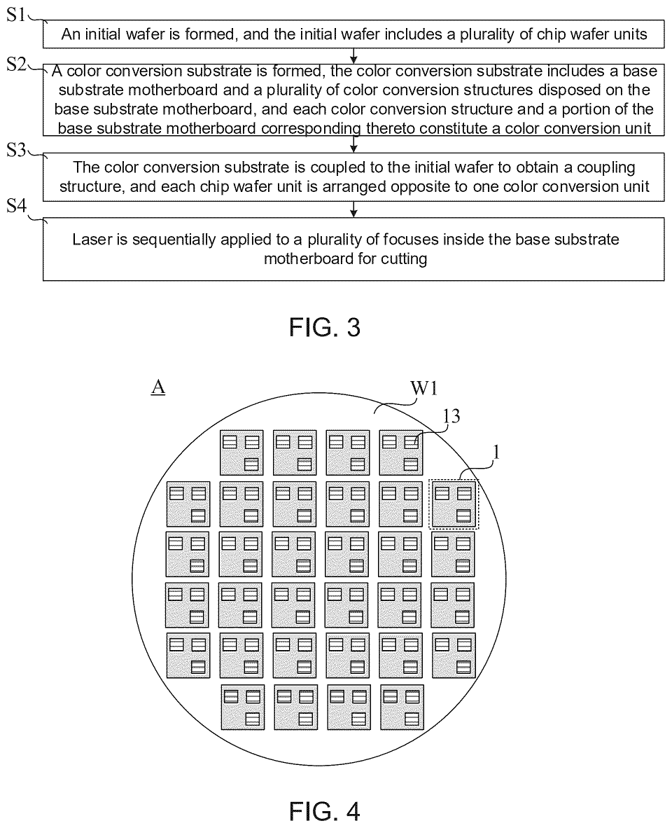

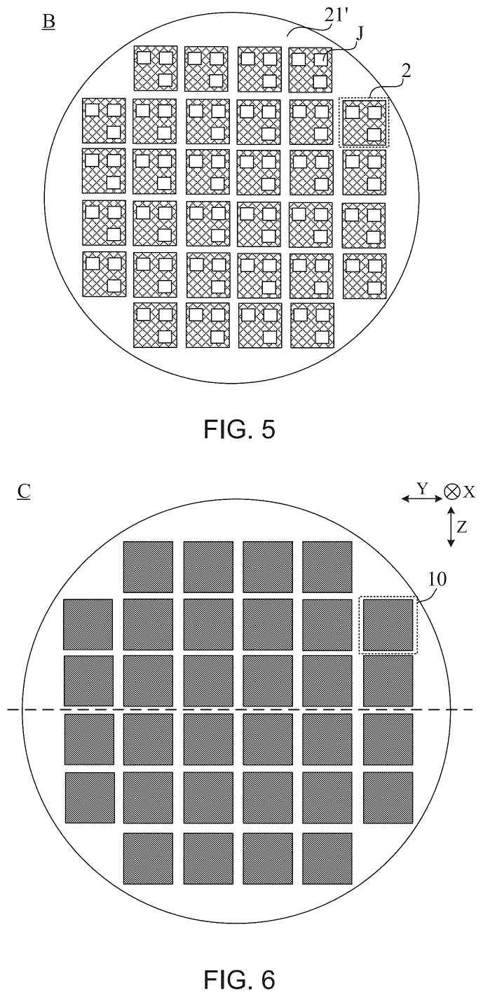

FIG. 5 is a side view showing a structure corresponding to a step S4 of the manufacturing method in FIG. 3;

FIG. 8 is an enlarged structural view taken along the section line FF in FIG. 7;

FIG. 9 is an enlarged view of the region E in FIG. 7;

FIG. 10 is a side view showing a structure corresponding to steps S11 to S14 of a manufacturing method, in accordance with some embodiments;

FIG. 11 is a side view showing a structure corresponding to a step S15 of a manufacturing method, in accordance with some embodiments;

FIG. 12 is a side view showing a structure corresponding to a step S16 of a manufacturing method, in accordance with some embodiments;

FIG. 13 is a side view showing a structure corresponding to a step S21 of a manufacturing method, in accordance with some embodiments;

FIG. 14 is a side view showing a structure corresponding to steps S22 and S23 of a manufacturing method, in accordance with some embodiments;

FIG. 15 is a side view showing a structure corresponding to steps S24 and S31 of a manufacturing method, in accordance with some embodiments;

FIG. 16 is a side view showing a structure corresponding to a step S32 of a manufacturing method, in accordance with some embodiments;

FIG. 17 is a side view showing a structure corresponding to a step S33 of a manufacturing method, in accordance with some embodiments;

FIG. 18 is a side view showing a structure corresponding to a step S34 of a manufacturing method, in accordance with some embodiments;

FIG. 19 is a side view showing a structure corresponding to a step S35 of a manufacturing method, in accordance with some embodiments; and

FIG. 20 is a top view showing a structure corresponding to a step S6 of a manufacturing method, in accordance with some embodiments.

### DETAILED DESCRIPTION

The technical solutions in embodiments of the present disclosure will be described clearly and completely with reference to the accompanying drawings. However, the described embodiments are merely some but not all of embodiments of the present disclosure. All other embodiments obtained on the basis of the embodiments of the present disclosure by a person of ordinary skill in the art shall be included in the protection scope of the present disclosure.

Unless the context requires otherwise, throughout the description and claims, the term “comprise” and other forms thereof such as the third-person singular form “comprises” and the present participle form “comprising” are construed as an open and inclusive meaning, i.e., “included, but not limited to”. In the description of the specification, terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, specific features, structures, materials, or characteristics described herein may be included in any one or more embodiments or examples in any suitable manner.

Hereinafter, the terms such as “first” and “second” are used for descriptive purposes only, but are not to be construed as indicating or implying the relative importance or implicitly indicating the number of indicated technical features. Thus, features defined with “first” and “second” may explicitly or implicitly include one or more of the features. In the description of the embodiments of the present disclosure, the term “multiple” “a plurality of” or “the plurality of” means two or more unless otherwise specified.

In the description of some embodiments, the expressions “coupled” and “connected” and derivatives thereof may be used. The term “connected” should be understood in a broad sense. For example, the term “connected” may represent a fixed connection, a detachable connection, or a one-piece connection; alternatively, the term “connected” may represent a direct connection, or an indirect connection through an intermediate medium. The term “coupled”, for example, indicates that two or more components are in direct physical or electrical contact. However, the term “coupled” or “communicatively coupled” may also indicate that two or more components are not in direct contact with each other, but still cooperate or interact with each other. The embodiments disclosed herein are not necessarily limited to the context herein.

The phrase “at least one of A, B and C” has the same meaning as the phrase “at least one of A, B or C”, both including following combinations of A, B and C: only A, only B, only C, a combination of A and B, a combination of A and C, a combination of B and C, and a combination of A, B and C.

The phrase “A and/or B” includes following three combinations: only A, only B, and a combination of A and B.

The phrase “applicable to” or “configured to” used herein means an open and inclusive expression, which does not exclude devices that are applicable to or configured to perform additional tasks or steps.

In addition, the phrase “based on” used is meant to be open and inclusive, since a process, step, calculation or other action that is “based on” one or more of the stated conditions or values may, in practice, be based on additional conditions or values exceeding those stated.

The term such as “about”, “substantially” or “approximately” as used herein includes a stated value and an average value within an acceptable range of deviation of a particular value determined by a person of ordinary skill in the art, considering measurement in question and errors associated with measurement of a particular quantity (i.e., limitations of a measurement system).

The term such as “parallel”, “perpendicular” or “equal” as used herein includes a stated case and a case similar to the stated case within an acceptable range of deviation determined by a person of ordinary skill in the art, considering measurement in question and errors associated with measurement of a particular quantity (i.e., limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be, for example, that a difference between two equals is less than or equal to 5% of either of the two equals.

It will be understood that, when a layer or element is referred to as being on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views as idealized exemplary drawings. In the accompanying drawings, thicknesses of layers and sizes of regions are enlarged for clarity. Variations in shape relative to the accompanying drawings due to, for example, manufacturing technologies and/or tolerances may be envisaged. Therefore, the exemplary embodiments should not be construed as being limited to the shapes of the regions shown herein, but including deviations due to, for example, manufacturing. For example, an etched region shown in a rectangular shape generally has a feature of being curved. Therefore, the regions shown in the accompanying drawings are schematic in nature, and their shapes are not intended to show actual shapes of the regions in an apparatus, and are not intended to limit the scope of the exemplary embodiments.

In some embodiments, as shown in FIG. 2, the chip structure 10 includes a chip wafer unit 1 and a color conversion unit 2 disposed on a light exit side of the chip wafer unit 1. The chip wafer unit 1 is configured to emit light of at least one color of a plurality of colors, and the color conversion unit 2 is configured to perform color conversion on the color light emitted by the chip wafer unit 1.

For example, the chip wafer unit 1 includes a plurality of light-emitting layers 13, and each light-emitting layer 13 is configured to, for example, emit light of one color of the plurality of colors. The color conversion unit 2 includes color conversion portion(s) 241 and filling portion(s) 242 arranged corresponding to the light-emitting layers 13. Each color conversion portion 241 is arranged opposite to at least one light-emitting layer 13. Each filling portion 242 is arranged opposite to at least one light-emitting layer 13. Each light-emitting layer 13 is arranged corresponding to a color conversion portion 241 or a filling portion 242.

In some examples, the color of light emitted by each light-emitting layer 13 of a plurality of light-emitting layers 13 is not necessarily the same.

For example, a part of the plurality of light-emitting layers 13 emits blue light, a part of the plurality of light-emitting layers 13 emits green light, and a part of the plurality of light-emitting layers 13 emits red light.

In some other examples, each light-emitting layer 13 of the plurality of light-emitting layers 13 emits light of the same color.

Each light-emitting layer 13 emitting light of the same color will be taken as an example for description below.

The single-color light emitted by the light-emitting layer 13 exits, for example, as light of the same color after passing through the filling portion 242. The single-color light emitted by the light-emitting layer 13 is converted into light of another color by the color conversion portion 241 and exits. Therefore, the chip structure 10 can emit light of a plurality of colors.

For example, the chip structure 10 includes a functional region AA and a peripheral region AN surrounding the functional region AA. Functional structures in the chip structure 10, such as the light-emitting layers 13, the color conversion portions 241 and the filling portions 242, are located in the functional region AA.

For example, the functional structures of the chip structure 10 further include an anode and a cathode located on two opposite sides of the light-emitting layer 13.

When manufacturing the chip structure, for example, a plurality of chip structures are formed on a motherboard and then the motherboard is cut to obtain the plurality of chip structures.

In some examples, a diamond cutter is used to cut the motherboard: or a grinding wheel cutter is used to saw the motherboard.

In this way, defects such as cutting debris and micro-cracks are likely to occur at edges of the chip structures, which can easily lead to a problem of low yield of the chip structures. In addition, cutting the motherboard in this way results in low accuracy and low efficiency.

In some other examples, a laser surface cutting process is used to cut the motherboard. The laser beam is irradiated on a surface of the motherboard and cuts along a thickness direction of the motherboard.

In this way, in order to ensure that the plurality of chip structures included in the motherboard are completely separated, the laser beam needs to be irradiated from a surface to an opposite surface of the motherboard, and the energy of the laser beam needs to cause the motherboard to be penetrated. Therefore, the energy of the laser beam needs to be kept within a high range to realize cutting of the motherboard. Heat is generated during laser cutting. The higher the energy of the laser beam, the larger the range of the heat-affected zone of the laser beam. In this way, the range of the heat-affected zone of the laser may cover the functional region of the chip structure, so that the light-emitting layers in the functional region may be affected by the laser, which leads to the problem that the chip structure cannot emit light normally.

In light of this, some embodiments of the present disclosure provide a chip structure, a method for manufacturing a chip structure, and a display apparatus, to overcome the above problems. The chip structure 10, the method for manufacturing the chip structure, and the display apparatus 100 provided in some embodiments of the present disclosure will be introduced below.

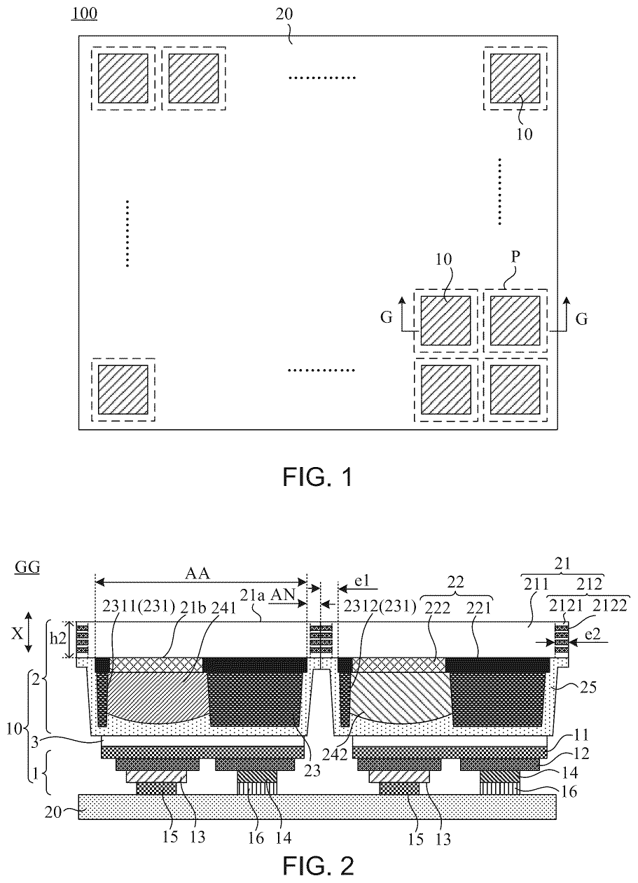

In the present disclosure, FIG. 1 is a plan view showing a structure of the display apparatus 100, and FIG. 2 is a sectional structural view of the display apparatus 100 in FIG. 1. FIG. 9 is an enlarged structural view of an edge portion 212 including original layers 2121 and modified layers 2122 that are alternately arranged.

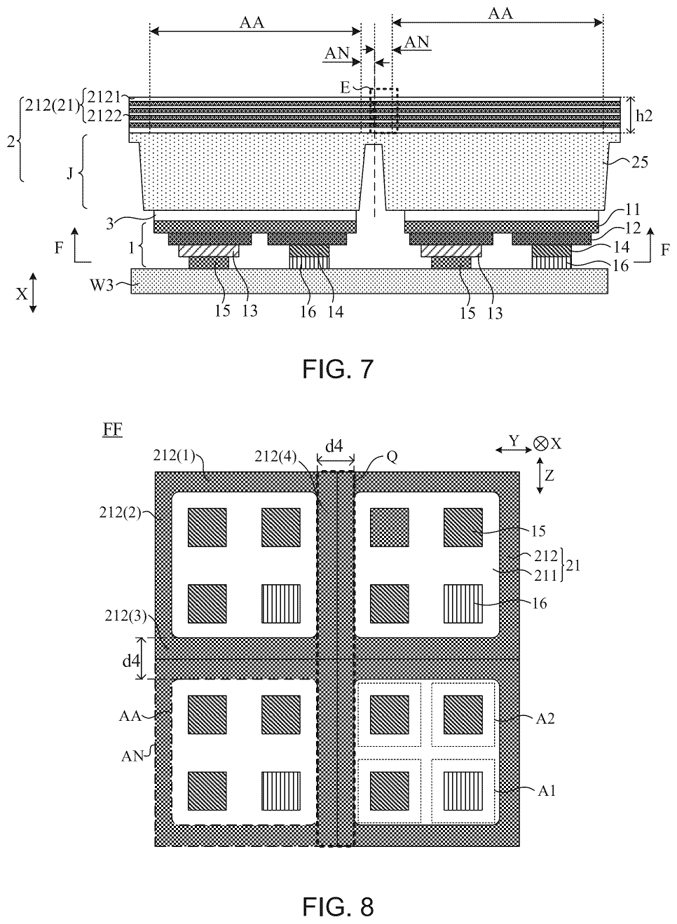

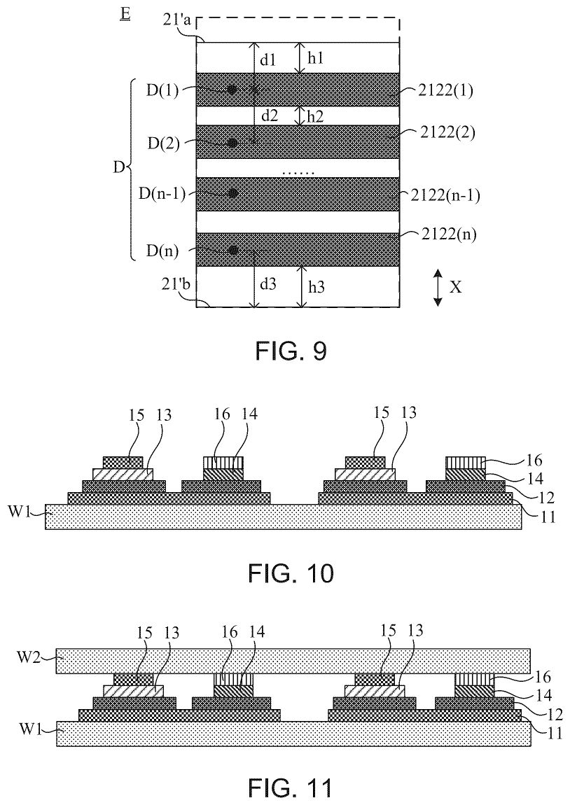

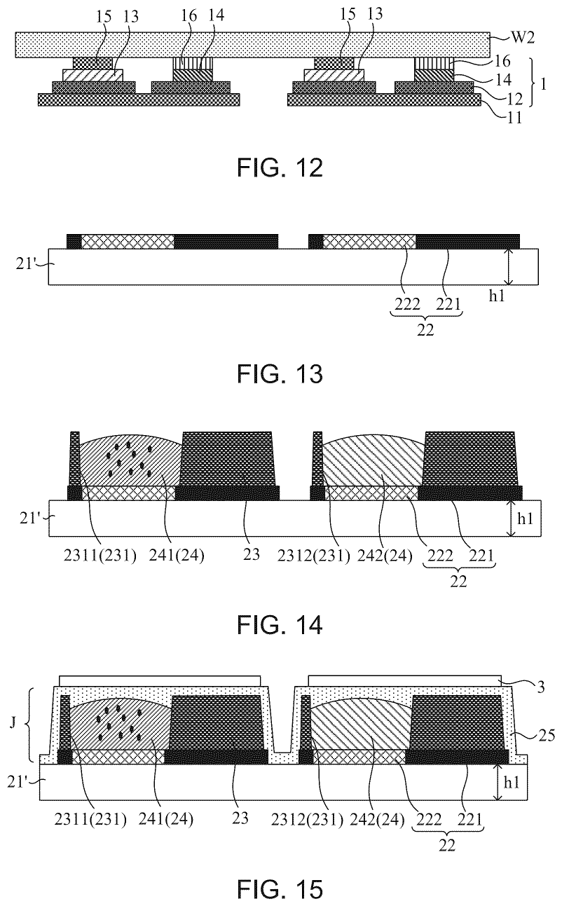

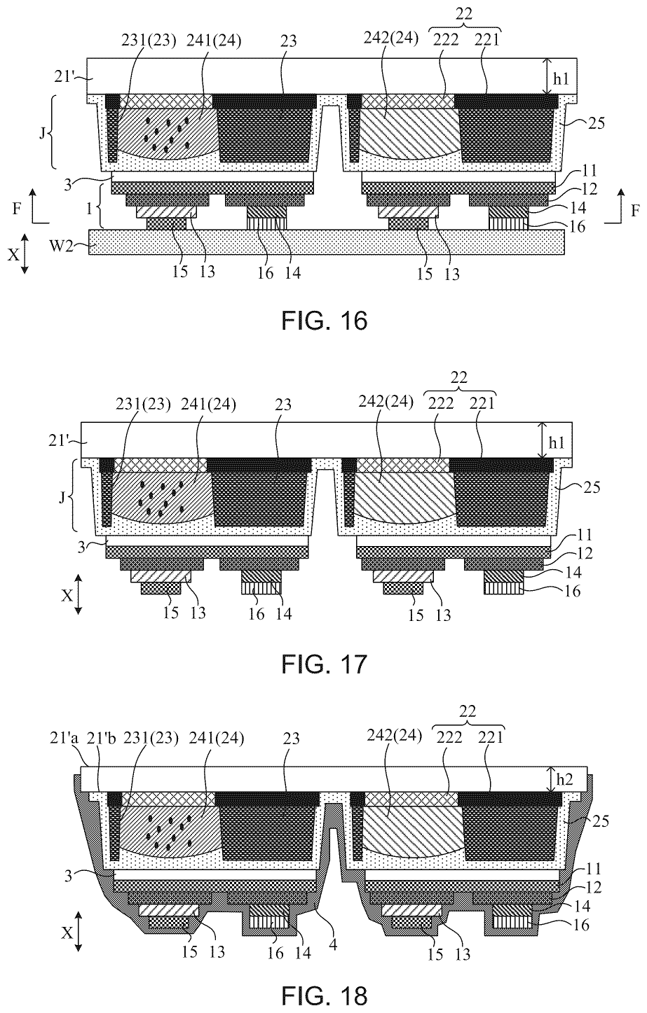

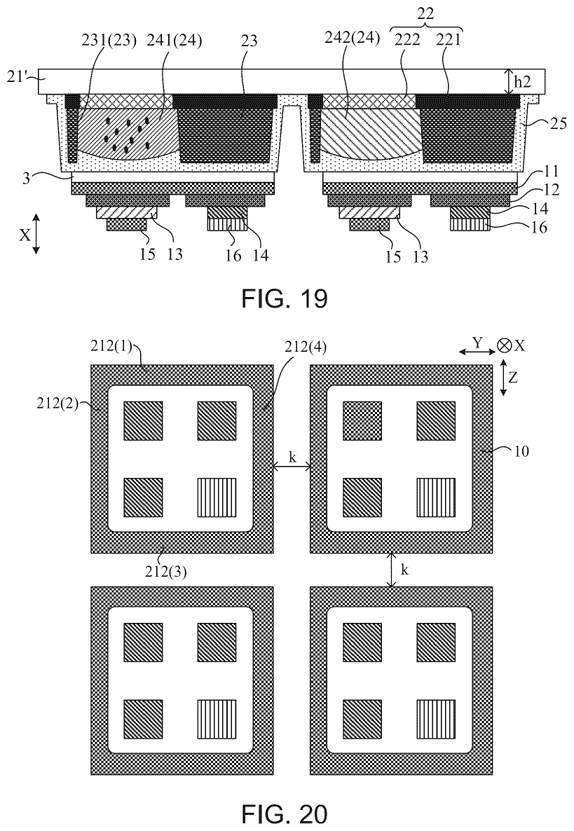

FIG. 6 is a top view showing a structure of a coupling structure C. FIG. 7 is a sectional view showing a structure of a coupling structure C after being cut along a cutting lane Q. FIG. 8 is an enlarged view showing a structure of a cutting lane Q. FIGS. 10, 11 and 12 are side views showing corresponding structures in a process of fabricating the chip wafer unit 1. FIGS. 13, 14 and 15 are side views showing corresponding structures in a process of fabricating the color conversion unit 2. FIGS. 16, 17, 18 and 19 are side views showing structures corresponding to steps of a process of thinning a base substrate motherboard 21′ before the laser cut the base substrate motherboard 21′ and after an initial wafer A and a color conversion substrate B are coupled.

FIGS. 8 and 20 are top views showing structures in the manufacturing process where the light-emitting layers 13 and other structures in the chip wafer unit 1 are removed to obtain the chip structure 10 that only includes the base substrate 21 and a pad layer (e.g., a first pad 15 and a second pad 16).

Some embodiments of the present disclosure provide a display apparatus 100. As shown in FIGS. 1 and 2, the display apparatus 100 includes a driving substrate 20 and a plurality of chip structures 10 described in any one of the embodiments.

For example, the driving substrate 20 includes, but is not limited to, a flexible printed circuit (FPC) and printed circuit board (PCB).

For example, a circuit structure is provided on a surface of the driving substrate 20 facing the chip structure 10. The chip structure 10 is electrically connected to the circuit structure on the driving substrate 20 through, for example, a pad layer (e.g., a first pad 15 and a second pad 16 shown in FIG. 2). The driving substrate 20 is configured to drive the chip structure 10 to emit light.

In some embodiments, as shown in FIG. 2, solder paste reflow is used to solder the pad layer (e.g., the first pad 15 and the second pad 16 shown in FIG. 2) to the circuit structure, to realize the connection between the chip structure 10 and the driving substrate 20. The driving substrate 20 outputs a light-emitting control signal, and the light-emitting control signal is transmitted to the light-emitting layer 13 through the pad layer, thus driving the light-emitting layer 13 to emit light.

For example, as shown in FIG. 1, the plurality of chip structures 10 included in the display apparatus 100 are arranged in an array.

For example, as shown in FIG. 1, the display apparatus 100 includes a plurality of pixels, and the plurality of pixels include sub-pixels P of at least three colors. The sub-pixels P of at least three colors include at least sub-pixels of a first color, sub-pixels of a second color and sub-pixels of a third color. The first color, the second color, and the third color are three primary colors (e.g., red (R), green (G), and blue (B)).

For example, each chip structure 10 is configured to emit light of at least one color of a plurality of colors.

In some examples, a single chip structure 10 emits light of a plurality of colors. For example, a single chip structure 10 includes a plurality of light-emitting regions, each light-emitting region emits light of one color, and colors of light emitted from the plurality of light-emitting regions are not necessarily the same.

When the chip structure 10 is applied to the display apparatus 100, the single chip structure 10 can emit light of a plurality colors. For example, the single chip structure 10 can emit light of three colors R, G, and B, so that the display apparatus 100 can realize polychrome display.

It can be understood that when the chip structures 10 are the same in size, in the chip structure 10 provided in the embodiments of the present disclosure, a single chip structure 10 can emit light of a plurality of colors. In this way, a light-emitting area corresponding to light of each color is smaller compared with the design in which a single chip structure can only emit light of a single color, so that the display apparatus 100 has high pixel accuracy and good display effects. As for the specific structure of the chip structure 10, reference can be made to the following description.

Some embodiments of the present disclosure further provide a method for manufacturing the chip structure 10.

As shown in FIG. 3, the method for manufacturing the chip structure 10 includes steps S1 to S4.

In S1, as shown in FIG. 4, an initial wafer A is formed. The initial wafer A includes a plurality of chip wafer units 1.

For example, as shown in FIG. 4, each chip wafer unit 1 includes a plurality of light-emitting layers 13. Each light-emitting layer 13 is configured to emit light of one color of the plurality of colors. For example, the plurality of light-emitting layers 13 emit light of the same color; or at least two of the plurality of light-emitting layers 13 emit light of different colors.

The light of the plurality of colors includes, but is not limited to, blue light, red light, and green light.

For example, the light-emitting layer 13 is a multiple quantum well (MQW).

For example, a shape of the initial wafer A includes, but is not limited to, a circle.

For example, a shape of the chip wafer unit 1 includes, but is not limited to, a rectangle.

In S2, as shown in FIG. 5, a color conversion substrate B is formed. The color conversion substrate B includes a base substrate motherboard 21′ and a plurality of color conversion structures J disposed on the base substrate motherboard 21. Each color conversion structure J and a portion of the base substrate motherboard 21 corresponding thereto constitute a color conversion unit 2.

For example, the base substrate motherboard 21′ is made of a transparent material. The material of the base substrate motherboard 21′ includes, but is not limited to, any one of glass, sapphire, silicon carbide, silicon, gallium arsenide or aluminum nitride.

For example, the color conversion substrate B has the same shape as the initial wafer A.

For example, a shape of the base substrate motherboard 21′ includes, but is not limited to, a circle.

For example, the color conversion unit 2 has the same shape as the chip wafer unit 1.

It should be noted that the preparation order of steps S1 and S2 is not limited, and it is only used here as an illustration of a possible implementation.

In S3, as shown in FIG. 6, the color conversion substrate B is coupled to the initial wafer A to obtain a coupling structure C. Each chip wafer unit 1 is arranged opposite to one color conversion unit 2.

For example, as shown in FIGS. 4 and 5, a size of the initial wafer A is 4 inches or 6 inches, and a size of the color conversion substrate B is the same as the size of the initial wafer A.

For example, as shown in FIG. 2, the chip wafer unit 1 and the color conversion unit 2 are coupled through a connection layer 3.

For example, the connection layer 3 includes, but is not limited to, an adhesive layer or a bonding layer.

In some examples, a bonding process is used to couple the color conversion substrate B and the initial wafer A.

In some other examples, an adhering process is used to couple the color conversion substrate B and the initial wafer A.

This is only used as an illustration of a possible implementation, and is not intended to limit the specific implementations of the present disclosure.

In S4, as shown in FIGS. 7, 8 and 9, laser is sequentially applied to a plurality focuses D inside the base substrate motherboard 21 for cutting.

The plurality of focuses D are arranged sequentially in a first direction X, the first direction X being perpendicular to a surface of the base substrate motherboard 21′ away from the plurality of color conversion structures J.

The base substrate motherboard 21′ is subjected to cutting to form a plurality of base substrates 21. Each base substrate 21 includes a body portion 211 and an edge portion 212 surrounding the body portion 211. The edge portion 212 includes original layers 2121 and modified layers 2122 that are alternately arranged in the first direction X, and layers located on two outermost sides in the first direction X are both original layers 2121,

By applying the laser to the plurality of focuses D inside the base substrate motherboard 21′ for cutting, in the process of forming the chip structure 10, the energy of the laser during each laser cutting is lower compared with the energy of the laser using a surface cutting. Therefore, the range of the heat-affected zone of the laser beam is reduced, and the influence on the functional structures (such as the light-emitting layers 13) in the chip structure 10 during the laser cutting is avoided, and in turn the problem of poor luminescence in the chip structure 10 is avoided.

It should be noted that when the laser is applied to the base substrate motherboard 21′ for cutting, a region near the laser incision (the heat-affected zone of the laser) is heated, and structure(s) in this region will undergo certain changes due to the heat of the laser. The base substrate motherboard 21′ is, for example, glass. When the laser is applied to the inside of the base substrate motherboard 21′ for cutting, the laser is applied to any focus D for cutting, the focus D serves as a center, and in the range of the heat-affected zone of the laser, chemical bonds of atoms in the glass (such as silicon-oxygen covalent bonds (Si—O bonds)) is broken due to the laser. Therefore, stress layers are generated in the base substrate motherboard 21′, and a portion between any two stress layers is not affected by the heat of the laser. Thus, atoms within the portion maintain their original structures and do not change. In this way, in the chip structure 10, a special structure is formed in which the edge portion 212 of the base substrate 21 includes original layers 2121 and modified layers 2122 that are alternately arranged. The modified layers 2122 are the stress layers generated during the laser cutting process.

The base substrate 21 is obtained by cutting the base substrate motherboard 21′, and a side surface of the base substrate 21 is a cutting face of the base substrate motherboard 21′ (a surface separated after the interior is cut by the laser); or, the side surface of the base substrate 21 is a part of the side surface of the base substrate motherboard 21′.

For example, as shown in FIG. 8, in the coupling structure C, a spacing region between functional regions AA of any two chip structures 10 is a cutting lane Q, and the base substrate motherboard 21′ includes a plurality of cutting lanes Q. The laser cuts along each cutting lane Q. When the laser is cutting along a single cutting lane Q, the laser is applied to N focuses D inside the base substrate motherboard 21′ in sequence, and the N focuses are all located in a single cutting lane Q, where N is a positive integer and is greater than or equal to 2 (N≥2). When cutting each cutting lane Q, the number of focuses D to which the laser is applied is the same or not necessarily the same.

In the following description, considering an example in which the laser cuts one cutting lane Q, applying the laser to the N focuses D inside the base substrate motherboard 21′ for cutting includes the following steps.

As shown in FIG. 9, an energy focal point of the laser beam is first aligned with the first focus D(1); and then, the laser beam moves in the cutting lane Q along a Y direction or Z direction shown in FIG. 8. A moving path of the laser beam is a laser cutting path; the laser cutting path is located in a plane that the focus D is located in and is parallel to a first surface 21′a or a second surface 21′b of the base substrate motherboard 21′, and the laser cutting path is parallel to the Y direction or Z direction shown in FIG. 8.

The above steps are repeated until the energy focal point of the laser beam is aligned with the Nth focus D(n) and the cutting of the base substrate motherboard 21′ is completed.

Referring to FIG. 9, when the laser is applied to any focus D for cutting, a modified layer 2122 is formed in the base substrate motherboard 21′ due to the laser. When the laser is applied to N focuses D for cutting in sequence, N modified layers 2122 are formed accordingly.

The cutting path during each laser cutting is located within a cutting lane Q. For example, the laser uses a 3-focus or 4-focus cutting. It should be noted that the 3-focus or 4-focus cutting described here means that the laser is applied to the 3 or 4 focuses inside the base substrate motherboard 21′ in sequence to perform cutting. The number of focuses during laser cutting is only used as an illustration of a possible implementation, and is not intended to limit the specific implementations of the present disclosure.

During the manufacturing process of the chip structure 10, the laser cuts M cutting lanes Q in total, where M is a positive integer, and the laser cuts the first cutting lane Q(1) to the m-th cutting lane Q(m) in sequence.

In some examples, when the laser cuts the 1st to mth cutting lanes Q, the number N of focuses D used for each cutting is the same.

For example, when the laser cuts the first cutting lane Q(1) to the m-th cutting lane Q(m), the 3-focus cutting is used.

In some other examples, when the laser cuts the 1st to mth cutting lanes Q, the number N of focuses D used in each cutting is not necessarily the same.

For example, the laser cuts the first cutting lane Q(1) using the 3-focus cutting; the laser cuts the second cutting lane Q(2) using the 4-focus cutting; the laser cuts the third cutting lane Q(3) using the 3-focus cutting; and the laser cuts the m-th cutting lane Q (m) using a 5-focus cutting.

As another example, when the laser cuts the 1st to mth cutting lanes Q, the number N of focuses D used for each cutting is different.

For example, a plurality of side surfaces of the base substrate 21 included in the chip structure 10 are all cutting faces of the base substrate motherboard 21′, and the plurality of side surfaces are obtained after the laser cuts a plurality of cutting lanes Q. It can be understood that when the laser cuts the plurality of cutting lanes Q, the laser is applied to the same number of focuses D inside the base substrate motherboard 21′ each time. In this case, the plurality of side surfaces of the base substrate 21 include the same number of modified layers 2122. When the laser cuts the plurality of cutting lanes Q, the number of focuses D to which the laser is applied each time in the base substrate motherboard 21′ is not necessarily the same. In this case, the number of modified layers 2122 included in each of the plurality of side surfaces is not necessarily the same.

Therefore, in the chip structure 10, as shown in FIG. 8, the base substrate 21 has a special structure including a body portion 211 and an edge portion 212 surrounding the body portion 211. The edge portion 212 includes a plurality of sub-portions 212(k) that is in one-to-one correspondence with the plurality of side surfaces of the base substrate 21 (where k is the number of side surfaces of the base substrate 21, and k side surfaces respectively correspond to k sub-portions of the edge portion 212), and the plurality of sub-portions 212(k) of the edge portion 212 each include the same number of modified layers 2122; alternatively, the number of modified layers 2122 included in each of the plurality of sub-portions of the edge portion 212 is not necessarily the same. The number of modified layers 2122 included in each sub-portion 212(k) of edge portion 212 is the same as the number of focuses D when the laser cuts the sub-portion.

As shown in FIG. 8, the base substrate 21 is, for example, rectangular and includes four side surfaces. Correspondingly, the edge portion 212 of the base substrate 21 includes four sub-portions, which are a first sub-portion 212(1) and a second sub-portion 212(2), a third sub-portion 212(3) and a fourth sub-portion 212(4). The first sub-portion 212(1), second sub-portion 212(2), third sub-portion 212(3) and fourth sub-portion 212(4) each include, for example, four modified layers 2122. Alternatively, the first sub-portion 212(1) and the second sub-portion 212(2) each include three modified layers 2122, and the third sub-portion 212 (3) and the fourth sub-portion 212(4) each include four modified layers 2122. Alternatively, the first sub-portion 212(1) includes three modified layers 2122, the second sub-portion 212(2) includes four modified layers, and the third sub-section 212(3) and the fourth sub-section 212(4) each include five modified layers 2122.

The laser beam cuts from a side of the color conversion substrate B and is applied to a plurality of focuses D inside the coupling structure C. As shown in FIG. 7, when the laser cuts the coupling structure C, compared with a case where the laser cuts the base substrate motherboard 21′ from the side of the color conversion substrate B, if the laser cuts the base substrate motherboard 21′ from a side of the initial wafer A, a distance between an output position of the laser and the focus D is larger. It can be understood that the longer the distance between the output position of the laser and the focus D, the more difficult it is to accurately locate the position of the focus D. When the location of the focus D is shifted and exceeds a range corresponding to the cutting lane Q, for example, the focus D is located in the functional region AA of the chip structure 10, during the laser cutting, functional structures in the functional region AA may be damaged by the laser irradiation, resulting in a problem of abnormal light emission of the chip structure 10.

The following description is introduced by taking an example in which each sub-portion included in the edge portion 212 includes the same number of modified layers 2122.

In some embodiments, in step S4, as shown in FIG. 7, the base substrate motherboard 21′ is cut from a side of the color conversion substrate B of the coupling structure C away from the initial wafer A.

In some examples, in the plurality of chip wafer units included in the initial wafer, a distance between any two adjacent chip structures is in a range of 20 μm to 100 μm, inclusive.

In some embodiments of the present disclosure, multi-focus cutting manner is used to cut the base substrate motherboard 21′, which can effectively narrow widths of the cutting lanes Q. As shown in FIG. 8, in the plurality of chip wafer units 1 included in the initial wafer A, a distance d4 between any two adjacent chip structures 10 is in a range of 20 μm to 50 μm, inclusive.

As shown in FIG. 7, in the plurality of chip structures 10 arranged in the coupling structure C, when the distance d4 between functional regions AA of any two adjacent chip structures 10 is small (for example, the distance d4 is in a range of 20 μm to 50 μm), by using this manner, the distance between the output position of the laser and the focus D is smaller, which is conducive to accurate locating of the focus D, thereby avoiding a problem that the laser focus D is difficult to align and deviates from the cutting lane Q due to the size of the cutting lane Q being too small.

It can be understood that, in order to ensure that the sizes of the obtained plurality of chip structures 10 are the same or substantially the same, the laser cutting path and a symmetry axis of the cutting lane Q are collinear or substantially collinear. As shown in FIG. 8, the cutting lane Q is, for example, in a shape of a rectangle, and the rectangle has two symmetry axes. The symmetry axis of the cutting lane Q mentioned here is a symmetry axis consistent with an extending direction of a length of the cutting lane Q. For example, as for the cutting lane Q shown in FIG. 8, the laser cutting path is collinear or substantially collinear with the symmetry axis of the cutting lane Q extending in the direction Z shown in the figure.

In some embodiments, in step S4, as shown in FIG. 9, the laser is sequentially applied to N focuses D inside the base substrate motherboard 21′ for cutting, where N is a positive integer and N≥2, a focus D farthest from the initial wafer A is the first focus D(1), and a focus D closest to the initial wafer A is the Nth focus D(n). A surface of the base substrate motherboard 21′ away from the initial wafer A is the first surface 21′a, and a surface of the base substrate motherboard 21′ close to the initial wafer A is the second surface 21′b.

In some examples, as shown in FIG. 9, a distance d1 between the first focus D(1) and the first surface 21′a is greater than or equal to a distance d2 between any two adjacent focuses D.

In a case where the base substrate motherboard 21′ is made of glass, when the laser is applied to a position of the focus D in the base substrate motherboard 21′, cracks will be created inside the base substrate motherboard 21′ near the position of the focus D, and the cracks will extend from the position of the focus D to a certain range. By controlling the distance d1 between the first focus D(1) and the first surface 21′a, it is possible to avoid that the cracks created inside the base substrate motherboard 21′ extend to the first surface 21′a of the base substrate motherboard 21′ when the laser is applied to the interior of the base substrate motherboard 21′, and in turn prevent the first surface 21′a of the base substrate motherboard 21′ from being cracked and fragmented.

In some other examples, as shown in FIG. 9, a distance d3 between the Nth focus D(n) and the second surface 21′b is greater than or equal to the distance d2 between any two adjacent focuses D.

By controlling the distance d3 between the Nth focus D(n) and the second surface 21′b, it is possible to avoid that the cracks created inside the base substrate motherboard 21′ extend to the second surface 21′b of the base substrate motherboard 21′ when the laser is applied to the interior of the base substrate motherboard 21′, and in turn prevent the second surface 21′b of the base substrate motherboard 21′ from being cracked and fragmented.

In yet some other examples, as shown in FIG. 9, the distance d1 between the first focus D(1) and the first surface 21′a is greater than or equal to the distance d2 between any two adjacent focuses D, and the distance d3 between the Nth focus D(n) and the second surface 21′b is greater than or equal to the distance d2 between any two adjacent focuses D.

With reference to the above description, by controlling the distance d1 between the first focus D(1) and the first surface 21′a and the distance d3 between the Nth focus D(n) and the second surface 21′b, the cracks created inside the base substrate motherboard 21′ will not extend to the surfaces of the base substrate motherboard 21′ when the laser is applied to the interior of the base substrate motherboard 21′ for cutting, thus preventing the surfaces of the base substrate motherboard 21′ from being cracked and fragmented.

For example, the distance d2 between any two adjacent focuses D is in a range of 15 μm to 35 μm, such as 15 μm, 20 μm, or 35 μm.

As another example, the distance d1 between the first focus D(1) and the first surface 21′a of the base substrate motherboard 21′ is in a range of 15 μm to 35 μm, such as 15 μm, 20 μm, or 35 μm. Further, the distance d1 between the first focal D(1) and the first surface 21′a of the base substrate motherboard 21′ is greater than or equal to 20 μm.

For yet another example, the distance d3 between the Nth focus D(n) and the second surface 21′b of the base substrate motherboard 21′ is in a range of 15 μm to 35 μm, such as 15 μm, 20 μm, or 35 μm. Further, the distance d3 between the Nth focus D(n) and the second surface 21′b of the base substrate motherboard 21′ is greater than or equal to 20 μm.

By appropriately increasing the distance d1 between the first focus D(1) and the first surface 21′a of the base substrate motherboard 21′ and the distance d3 between the Nth focus D(n) and the second surface 21′b of the base substrate motherboard 21 it can effectively prevent the cracks created inside the base substrate motherboard 21′ when the laser is applied to the focuses from extending to the surfaces of the base substrate motherboard 21′ when the laser is applied to the focus in the base substrate motherboard 21′ for cutting, and in turn prevent the surfaces of the base substrate motherboard 21′ from being cracked and fragmented.

It should be noted that, on the premise of ensuring that d1 d2 and d3 a d2, it should also be ensured that the value of d1+k×d2+d3 is equal to a thickness (e.g., a size in the direction Z shown in FIG. 9) of the base substrate motherboard 21′, where k is the number of distances d2 between N focuses arranged along the first direction X, and k=N −1.

For example, the thickness of the base substrate motherboard 21′ is 100 μm. The following description is introduced by taking an example in which the thickness of the base substrate motherboard 21′ is 100 μm.

In some examples, 3-focus cutting is used, N=3, and the laser is applied to 3 focuses D inside the base substrate motherboard 21′ in sequence to perform cutting, where d1+2×d2+d3=100 μm.

For example, the distance d2 between any two adjacent focuses D is 18 μm. Correspondingly, d1+d3=100-18×2=64 μm. In this case, d1=d3=32 μm; or, d1=29 μm and d3=35 μm; or, d1=35 μm and d3=29 μm; or, d1=31 μm and d3=33 μm.

As another example, the distance d2 between any two adjacent focuses D is 15 μm. Correspondingly, d1+d3=100-15×2=70 μm. In this case, d1=d3=35 μm.

In some other examples, 4-focus cutting is used, N=4, and the laser is applied to 4 focuses D inside the base substrate motherboard 21′ in sequence to perform cutting, where d1+3×d2+d3=100 μm.

For example, the distance d2 between any two adjacent focuses D is 18 μm. Correspondingly, d1+d3=100−18×3=46 μm. In this case, d1=d3=23 μm; or, d1=18 μm and d3=28 μm; or, d1=28 μm and d3=18 μm; or, d1=20 μm and d3=23 μm.

As another example, the distance d2 between any two adjacent focuses D is 15 μm. Correspondingly, d1+d3=100−15×3=55 μm. In this case, d1=20 μm and d3=35 μm; or, d1=35 μm and d3=20 μm; or, d1=25 μm and d3=30 μm.

It should be noted that, the thickness of the base substrate motherboard 21′, the distance d2 between any two adjacent focuses D, and the distances (d1 and d3) between the focus D and the surfaces of the base substrate motherboard 21′ are only used as possible implementations and are not intended to limit the embodiments of the present disclosure.

For example, as shown in FIG. 9, the laser is applied to N focuses D inside the base substrate motherboard 21′ in sequence to perform cutting, so as to form N modified layers 2122 sequentially arranged in the first direction X; and a distance between any two adjacent modified layers 2122 in the first direction X is greater than 0.

In some embodiments of the present disclosure, the laser is applied to the base substrate motherboard 21′ to perform cutting, so as to obtain the plurality of chip structures 10. It can be understood that, opposite side surfaces of base substrates 21 included in any two adjacent chip structures 10 are cutting faces, which are obtained by applying the laser to the base substrate motherboard 21′ for cutting. During the laser cutting process, a region near the laser incision (the heat-affected zone of the laser) is heated, and the structure in this region will undergo certain changes under the heat influence of the laser.

It should be noted that the stress of a portion of the substrate motherboard 21′ that is close to the focus D and located within the heat-affected zone of the laser is different from the stresses of other positions located outside the heat-affected zone of the laser. This is reflected in the fact that in the chip structure 10, the original layers 2121 and the modified layers 2122 included in the edge portion 212 are subjected to different stresses. In addition, the body portion 211 and the original layers 2121 are not affected by the heat of the laser. Therefore, the body portion 211 and the original layers 2121 are subjected to the same stress.

Cracks will be created in the base substrate motherboard 21′ due to the laser, and the cracks extend from the focus D in directions away from the focus D, and the extending directions of the cracks are divergent and irregular. Therefore, a light reflectivity of a part that is close to the focus D and located within the heat-affected zone of the laser (for example, the reflectivity to light of a wavelength in a range of 380 μm to 780 μm) is different from a light reflectivity of the rest in the base substrate motherboard 21. This is reflected in the chip structure 10 as follows: the light reflectivity of the original layers 2121 and the light reflectivity of the modified layers 2122 are different, and the original layers 2121 and the body portion 211 have the same light reflectivity.

By controlling the energy of the laser beam within a certain range, the laser beam is applied to the focus D with lower energy. Therefore, the range of the heat-affected zone of the laser is smaller. Correspondingly, when the laser is applied to the focus D, the extending range of the created cracks is smaller. After cutting the plurality of focuses D in sequence, the plurality of formed modified layers 2122 have therebetween certain spacings along the first direction X, and do not be connected. In addition, since the extending range of the cracks created when the laser is applied to the focus D is smaller, in the finally formed chip structure 10, the modified layers 2122 only exist in the peripheral region AN of the chip structure 10 and do not extend into the functional region AA. Therefore, when the light emitted by the chip wafer unit 1 passes through the color conversion unit 2 and then exits, the part of the base substrate 21 located in the functional region AA has good light reflectivity, which ensures the light-emitting effect of the chip structure 10.

Layers of the edge portion 212 located on outermost two sides in the first direction X are both original layers 2121. The original layers 2121 and the modified layers 2122 are alternately arranged. It can be understood that the original layers 2121 have one more layer than the modified layers 2122, and the number of the original layers 2121 is P, where P=N+1.

By using a multi-focus cutting method, the laser acts on N focuses D in the base substrate motherboard 21′ in sequence. When the laser cuts the base substrate motherboard 21′ of the same thickness, the greater the value N of the number of focuses D is set, the energy value of the laser beam acting on a single focus D can be correspondingly smaller, and the heat-affected zone during laser cutting can also be smaller. In this way, when forming the coupling structure C, the distance d4 between any two adjacent chip structures 10. The size of the coupling structure C can also be smaller, so that more chip structures 10 can be installed in the coupling structure C of the same size, thereby reducing the manufacturing cost of the chip structure 10.

With reference to the above description of step S4 (in which the laser is applied to the plurality of focuses D inside the base substrate motherboard 21′ in sequence for cutting), when the laser cuts the coupling structure C, using a multi-focus cutting method, the laser is applied to the plurality of focuses D inside the base substrate motherboard 21′ in sequence for cutting. In this way, compared with the surface cutting method, the energy of the laser beam that the laser is applied each time is lower. Correspondingly, the range of the heat-affected zone will be smaller, so that the spacing between the chip structures 10 arranged in the coupling structure C is smaller. That is, the width of the cutting lane Q is smaller, so that more chip structures 10 can be cut from the coupling structure C of the same size. It can be understood that, in this way, more chip structures 10 can be prepared with the same time and materials, which reduces the manufacturing cost of the chip structure 10 and improves the manufacturing efficiency of the chip structure 10.

As shown in FIG. 8, a region between the functional regions AA of any two adjacent chip structures 10 is a cutting lane Q. When the laser is applied to the base substrate motherboard 21′ for cutting, the plurality of focuses D are located in the same cutting lane Q, and the laser cuts along the cutting surface. The cutting surface mentioned here is a plane that the plurality of focuses D are located in and is perpendicular to the first surface 21′a or the second surface 21′b of the base substrate motherboard 21′. The cutting surface divides the cutting lane Q substantially into two parts (the two parts have the same or approximately the same size).

For example, as shown in FIG. 7, during the manufacturing process of the chip structure 10, each time the laser is used to cut the base substrate motherboard 21, a wavelength of the laser is less than 2000 nm.

For example, each time the laser is used to cut the base substrate motherboard 21′, the wavelength of the laser is 1024 nm.

In order to clearly describe the method of manufacturing the chip structure 10, the formation of one chip structure 10 will be described below as an example. It can be understood that the method of manufacturing the chip structure 10 is to first form a coupling structure C including a plurality of chip structures 10 arranged in an array, and then cut the coupling structure C to obtain the plurality of chip structures 10.

The specific implementation of each step in the preparation method of the chip structure 10 is introduced below. The chip structure 10 formed according to this embodiment is the chip structure 10 shown in FIG. 1 and FIG. 2.

For example, step S1 (in which the initial wafer A is formed, the initial wafer A including a plurality of chip wafer units 1) includes steps S11 to S16.

In S11, as shown in FIG. 10, a buffer layer 11 and N-type gallium nitride layers 12 that are stacked are formed on a first base W1.

For example, as shown in FIG. 10, the first base W1 is a silicon-based base or a sapphire base.

For example, as shown in FIG. 10, the buffer layer 11 and the N-type gallium nitride layers 12 are formed using a metal sputtering process or a chemical deposition process.

In S12, as shown in FIG. 10, a plurality of light-emitting layers 13 are formed on a side of the N-type gallium nitride layers 12 away from the first base W1.

In some embodiments, each light-emitting layer 13 of the plurality of light-emitting layers 13 is configured to emit light of one of a plurality of colors.

In some examples, the plurality of light-emitting devices 13 emit light of the same color.

For example, light of a plurality of colors includes, but is not limited to, blue light.

For example, as shown in FIG. 10, the light-emitting layer 13 includes, a quantum well layer.

For example, the quantum well layer is a blue quantum well, and the light-emitting layer 13 including the blue quantum well emits blue light.

For another example, the quantum well layer is a red quantum well, and the light-emitting layer 13 including the red quantum well emits red light.

For yet another example, the quantum well layer is a green quantum well, and the light-emitting layer 13 including the green quantum well emits green light.

In S13, as shown in FIG. 10, cathode transfer electrodes 14 are formed on the side of the N-type gallium nitride layers 12 away from the first base W1.

For example, the cathode transfer electrodes 14 and the plurality of light-emitting layers 13 are arranged in the same layer.

For example, as shown in FIG. 8, the chip structure 10 has a functional region AA. The functional region AA includes a connection region A1 and a plurality of light-emitting regions A2. The connection region A1 and the plurality of light-emitting regions A2 are arranged in an array. Each connection region A1 is provided therein with a single cathode transfer electrode 14.

Each light-emitting region A2 is provided therein with at least one light-emitting layer 13. When each light-emitting region A2 is provided therein with a plurality of light-emitting layers 13, the plurality of light-emitting layers 13 are connected to each other. The plurality of light-emitting layers 13 in each light-emitting region A2 are, for example, connected in series or in parallel.

For example, the cathode transfer electrode 14 is made of a conductive material. The material of the cathode transfer electrode 14 includes, but is not limited to, at least one of gold, silver, plumbum, tin, copper, titanium, aluminum, molybdenum, nickel gold or conductive silver glue.

In S14, as shown in FIG. 10, a pad layer is formed on a side of the plurality of light-emitting layers 13 away from the first base W1. The pad layer includes a second pad 16 and a plurality of first pads 15 that corresponds to the plurality of light-emitting layers 13.

For example, the pad layer is made of a conductive material.

The material of the pad layer includes, but is not limited to, at least one of gold, silver, copper, titanium, aluminum, molybdenum, niobium, nickel gold or conductive silver glue.

In some examples, the pad layer is of a single-layer structure.

For example, the pad layer is a copper layer.

In some other examples, the pad layer is of a multi-layer structure.

For example, the pad layer is of a laminated structure formed by sequentially stacking molybdenum niobium alloy/copper/copper nickel alloy (MoNb/Cu/CuNi).

For example, the pad layer is configured to realize connections between the chip structure 10 and other structures; the pad layer is also configured to transmit electrical signals.

In some examples, as shown in FIGS. 1 and 2, when the chip structure 10 is applied to the display apparatus 100, a plurality of chip structures 10 are disposed on the driving substrate 20 (e.g., FPC or PCB), and each chip structure 10 is connected to the driving substrate 20 via the first pads 15 and the second pad 16 in the pad layer.

For example, the first pads 15 and the second pad 16 are soldered to the circuit structures of the driving substrate 20 using solder paste reflow, thereby realizing the connection between the chip structure 10 and the driving substrate 20. The electrical signals generated by the driving substrate 20 are transmitted to the chip structure 10 through the pad layer.

In S15, as shown in FIG. 11, a second base W2 is formed on a side of the pad layer away from the first base W1.

For example, the second base W2 includes, but is not limited to, any one of glass, blue sapphire, and PI film.

In S16, as shown in FIG. 12, the first base W1 is removed.

For example, with reference to the above description of step S3 (in which the color conversion substrate B and the initial wafer A are coupled to obtain the coupling structure C), a side of the color conversion structure J away from the second base W2 is configured to be connected to the chip wafer unit 1, and the second base W2 serves as a temporary carrier to carry the color conversion structure J after the first base W1 is removed and before the color conversion structure J is connected to the chip wafer unit 1.

In some embodiments, step S2 (in which the color conversion substrate B is formed) includes steps S21 to S24.

In S21, as shown in FIG. 13, a color filter layer 22 is formed on the base substrate motherboard 21. The color filter layer 22 includes a black matrix 221 and a plurality of filter portions 222 defined by the black matrix 221.

For example, a thickness of the base substrate motherboard 21′ is h1.

For example, the color filter layer 22 is formed using processes such as coating, exposure, development, and post-baking.

For example, the black matrix 221 and the plurality of filter portions 222 defined by the black matrix 221 are formed using processes such as coating, exposure, development, and post-baking.

For example, each filter portion 222 is arranged corresponding to at least one light-emitting layer 13. The plurality of filter portions 222 include, for example, first filter portions, second filter portions, and third filter portions. The first filter portion, the second filter portion and the third filter portion are each arranged opposite to at least one light-emitting layer 13.

When each light-emitting region A2 includes a plurality of light-emitting layers 13, for example, the plurality of light-emitting layers 13 in each light-emitting region A2 are arranged corresponding to the same filter portion 222; alternatively, the plurality of light-emitting layers 13 in each light-emitting region A2 are respectively arranged corresponding to a plurality of filter portions 222,

For example, the base substrate motherboard 21′ includes, but is not limited to, a glass substrate, a quartz substrate, a plastic substrate, a sapphire substrate or a silicon-based substrate.

In the chip structure 10, light emitted by the light-emitting layers 13 passes through the filter portions 222 and then exits. By providing the filter portions 222, the color gamut of the light emitted by the light-emitting layers 13 can be improved, so as to improve the color gamut of the light emitted by the chip structure 10.

In S22, as shown in FIG. 14, a defining dam layer 23 is formed. The defining dam layer 23 is disposed on a side of the color filter layer 22 away from the base substrate motherboard 21. The defining dam layer 23 includes a plurality of opening regions 231 corresponding to the plurality of filter portions 222.

For example, the defining dam layer 23 is formed using processes such as coating, exposure, development, and post-baking.

For example, the plurality of opening regions 231 includes: first-type opening regions 2311 arranged corresponding to the first filter portions and the second filter portions, and second-type opening regions 2312 arranged corresponding to the third filter portions.

Each first-type opening region 2311 is arranged corresponding to a single first filter portion or a single second filter portion.

In S23, as shown in FIG. 14, the color conversion layer 24 is formed. The color conversion layer 24 includes a plurality of color conversion portions 241 and filling portion(s) 242 disposed in the opening regions 231.

For example, the color conversion layer 24 is formed in the opening regions using processes such as coating, exposure, development, and post-baking or using inkjet printing process.

For example, a quantum dot conversion portion is formed in the first-type opening region 2311. The light-emitting layer 13 in the light-emitting region A2 corresponding to the first-type opening region 2311 emits light of a color, which is converted into light of another color after passing through the quantum dot conversion portion.

For example, the quantum dot conversion portion uses red quantum dot luminescent material or red fluorescent material.

For another example, the quantum dot conversion portion uses green quantum dot luminescent material or green fluorescent material.

It should be noted that the material of the quantum dot conversion portion can be any material that can achieve the color conversion function. This is only used as an illustration of a possible implementation and is not intended to limit the specific implementations of the present disclosure.

For example, a scattering particle portion is formed in the second-type opening region 2312. The scattering particle portion uses, for example, scattering particles,

It should be noted that the scattering particle portion has good light transmittance. After the light emitted by the chip wafer unit 1 passes through the scattering particle portion, the intensity of the light will not change much and remains basically the same, so that the light emission effect of the chip structure 10 is guaranteed.

The light-emitting layer 13 in the light-emitting region A2 corresponding to the second-type opening region 2312 emits light of a color, which remains the light of the same color after passing through the scattering particles and exits. The scattering particles fill the second-type opening region 2312, so that the uniformity of the thickness of the defining dam layer 23 is good, and in turn the uniformity of the thickness of the chip structure 10 is good.

In S24, as shown in FIG. 15, an encapsulation layer 25 is formed. The encapsulation layer 25 covers the color filter layer 22, the defining dam layer 23 and the color conversion layer 24.

For example, a material of the encapsulation layer 25 has good sealing property and good heat resistance. The material of the encapsulation layer 25 includes, but is not limited to, any one of silicon nitride, silicon oxide, or silicon oxynitride.

For example, the encapsulation layer 25 is formed using a chemical vapor deposition (CVD) process.

By providing the encapsulation layer 25, it may be possible to effectively avoid that the color conversion layer 24 is corroded by water and oxygen or mechanically damaged when being exposed to the air for a long time, which affects the color conversion effect of the color conversion layer 24, and in turn improve the working stability of the color conversion layer 24 and improve the working stability of the chip structure 10. In addition, the color conversion layer 24 has good luminous efficiency and heat dissipation environment, so that the service life of the color conversion layer 24 is improved, and the service life of the chip structure 10 is increased.

In some embodiments, step S3 (in which the color conversion substrate B and the initial wafer A are coupled to obtain the coupling structure C) includes steps S31 to S36, or includes steps S31 to S37.

In S31, as shown in FIG. 15, the connection layer 3 is formed on a side of the encapsulation layer 25 away from the base substrate motherboard 21′.

For example, the chip wafer unit 1 and the color conversion unit 2 are bonded together through the connection layer 3, and the bonding effect of the connection layer 3 may be adhesive effect or metallic bonding effect.

This is only used as an illustration of a possible implementation, and is not intended to limit the specific implementation of the present disclosure.

In S32, as shown in FIG. 16, the chip wafer unit 1 and the color conversion unit 2 are coupled through the connection layer 3.

In S33, as shown in FIG. 17, the second base W2 is removed.

In S34, as shown in FIG. 18, a protective film 4 is attached to a side of the chip wafer unit 1 away from the color conversion unit 2. The protective film 4 covers the chip wafer unit 1 and the remaining part of the color conversion unit 2 other than the base substrate motherboard 21′, and the protective film 4 further covers the second surface 21′b of the base substrate motherboard 21′ and portions, proximate to the second surface 21′b, of the plurality of side surfaces of the base substrate motherboard 21′.

For example, the protective film 4 includes, but is not limited to, an acid-proof film,

In S35, as shown in FIG. 17, the base substrate motherboard 21′ is thinned.

For example, as shown in FIGS. 17 and 18, the base substrate motherboard 21′ is a glass substrate. When thinning the base substrate motherboard 21′, the chip wafer unit 1 with the protective film 4 attached is placed in an etching solution (e.g., a potassium nitrate solution), the portions covered by the protective film 4 will not be damaged by the etching solution, and an exposed portion of the base substrate motherboard 21′ is etched and thinned due to the etching solution. The thickness of the base substrate motherboard 21′ is reduced from h1 to h2.

In S36, as shown in FIG. 19, the protective film 4 is removed.

In some embodiments, after step S36, step S3 further includes step S37.

In S37, as shown in FIG. 7, a third base W3 is attached to the side of the chip wafer unit 1 away from the color conversion unit 2.

For example, the third base W3 has high temperature resistance and good ductility.

The third base W3 includes but is not limited to a blue film.

This is only used as an illustration of a possible implementation, and is not intended to limit the specific implementations of the present disclosure.

Further, after step S4 (in which the laser is applied to the plurality of focuses D inside the base substrate motherboard 21′ in sequence for cutting), the method further includes steps S5 and S6.

In S5, pressure is applied to the base substrate motherboard 21′ from a side of the base substrate motherboard 21′ away from the chip wafer unit 1, so that the base substrate motherboard 21′ is split along the cutting faces.

During the laser cutting process, the cracks generated by the laser in the base substrate motherboard 21′ do not extend to the surfaces of the base substrate motherboard 21′. It can be understood that the plurality of chip structures 10 are not completely separated at this time. Therefore, the coupling structure C after the laser cutting needs to undergo pressing and breaking, causing the base substrate motherboard 21′ to be disconnected along the cutting surfaces. As a result, the plurality of chip structures 10 are completely separated from each other.

In S6, as shown in FIG. 20, the third base W3 is stretched in the second direction Y and the third direction Z, so that a distance between any two adjacent chip structures 10 is greater than zero.

For example, as shown in FIG. 20, in step S6, the distance k between any two adjacent chip structures 10 changes from 0 in step S4 to k. For example, k is in a range of 20 μm to 30 μm.

Through step S6, after stretching the third base W3, the plurality of chip structures 10 can be further separated from each other. For example, in step S5, adjacent side surfaces of base substrates 21 of some adjacent chip structures 10 are not completely separated. Through step S6, portions of the adjacent base substrates 21 that are not completely separated can be further separated.

It should be noted that the size of k is related to the ductility of the third base W3, which is set according to the actual situations during the manufacturing process of the chip structure 10. This is only used as an illustration of a possible implementation and is not intended to limit the specific implementations of the present disclosure.

In S7, the third base W3 is removed.

For example, after step S6, the base substrate motherboard 21′ is divided into the plurality of base substrates 21 along the cutting surfaces, and each base substrate 21 corresponds to a single chip structure 10. At this time, the plurality of chip structures 10 located on the third base W3 are obtained. After the third base W3 is removed, the plurality of chip structures 10 are obtained.

The separation of the plurality of base substrates 21 is realized in step S5, so that the plurality of chip structures 10 are separated from each other. During the stretching process of the third base W3 in step S6, the distances between the plurality of chip structures 10 increase accordingly. For example, the plurality of chip structures 10 are grabbed by a grabbing device to be removed from the third base W3. In this way, a grabbing space for the chip structures 10 is increased, which facilitates the separation of the plurality of chip structures 10 from the third base W3.

It can be understood that in the aforementioned steps, the purpose of providing the third base W3 is to enable the plurality of chip structures 10 to be maintained on one surface of the third base W3 during the processes of step S5 (splitting) and step S6 (stretching), to avoid damage caused by accidental falling of the chip structures 10.

It can be understood that, in step S4, if the cutting surfaces of the base substrate motherboard 21′ have been completely separated after the laser cutting and the plurality of chip structures 10 have become independent structures, then there is no need to perform steps S5 and S6.

Some embodiments of the present disclosure provide a chip substrate 10. The chip structure 10 is formed, for example, using the above-mentioned manufacturing method.

As shown in FIGS. 1 and 2, the chip structure 10 includes: a chip wafer unit 1 and a color conversion unit 2 disposed on a light exit side of the chip wafer unit 1. The color conversion unit 2 includes a base substrate 21, and the base substrate 21 includes a body portion 211 and an edge portion 212 surrounding the body portion 211. The edge portion 212 includes original layers 2121 and modified layers 2122 alternately arranged along the first direction X. The light reflectivity of original layers 2121 and the light reflectivity of the modified layers 2122 are different.

In the edge portion 212, layers located on outermost two sides in the first direction X are both original layers 2121. The first direction X is perpendicular to the surface of the base substrate 21 away from the chip wafer unit 1.

For example, the light reflectivity described here refers to the reflectivity of the original layers 2121 and modified layers 2122 to light of a wavelength in a range of 380 μm to 780 μm.

For example, during the manufacturing process of the chip structure 10, with reference to the above description of the manufacturing method of the chip structure, the laser is applied to the N focuses inside the base substrate motherboard 21′ in sequence for cutting. The modified layers 2122 are portions of the base substrate motherboard 21′ that are close to the laser cutting surface(s) and undergo structural changes due to the laser. The original layers 2121 are portions of the base substrate motherboard 21′ that are close to the laser cutting surface(s) and not affected by the laser and maintains the original structures.

It should be noted that the base substrate 21 is obtained by cutting the base substrate motherboard 21′, and a side surface of the base substrate 21 is a cutting face of the base substrate motherboard 21′; or, the side surface of the base substrate 21 is a part of the side surface of the base substrate motherboard 21′. The original layers 2121 and the modified layers 2122 are all obtained through the laser being applied to the internal of the base substrate motherboard 21′ for cutting.

The structural changes described here include but are not limited to changes in the atomic structures of the material based on the base substrate 21 (e.g., changes caused by the broken of the chemical bonds of atoms in the glass (such as Si—O bonds) in the range of the heat-affected zone of the laser due to the laser) and/or changes in surface cracks visible to the naked eyes.

For example, as shown in FIG. 2, the base substrate 21 has a functional region AA and a peripheral region AN surrounding the functional region AA. An orthographic projection of the chip wafer unit 1 on the base substrate 21 is located in the functional region AA. The body portion 211 is located at least in the functional region AA, and the edge portion 212 is located in the peripheral region AN.

For example, the base substrate 21 is made of a transparent material. The material of the base substrate 21 includes but is not limited to glass.

For example, with reference to the above description of the manufacturing method of the chip structure 10, the plurality of side surfaces of the base substrate 21 are cutting surfaces obtained by the laser cutting the base substrate motherboard 21′ when forming the chip structure 10. For example, when the base substrate motherboard 21′ is made of glass, cracks will occur on the cutting surfaces during the laser cutting, causing structural changes in this part, in turn causing changes in the light reflectivity and stress of the cutting surfaces. However, the interior of the base substrate 21 is not affected by the laser, and the original structure of the material is maintained (the light reflectivity and stress have not changed). Thus, the base substrate 21 is formed, which includes the body portion 211 and the edge portion 212 that is of a special structure including original layers 2121 and modified layers 2122 that are alternately arranged.

With reference to the above description of the manufacturing method of the chip structure 10, it can be understood that the base substrate 21 is a one-piece structure, and the body portion 211 and the edge portion 212 are only used for a division of a part of the base substrate 21 that is or is not affected by the laser cutting during the manufacturing process of the chip structure 10, rather than the base substrate 21 consisting of the two portions. The body portion 211 is the part of the base substrate 21 that is not affected by the laser and does not change during the manufacturing process of the chip structure 10. The edge portion 212 is the part of the base substrate 21 that is close to the laser cutting path during the manufacturing process of the chip structure 10. The modified layers 2122 are the part that is affected by the laser and undergoes changes during the laser cutting in the manufacturing process of the chip structure 10.

For example, the light reflectivity of the modified layers 2122 of the base substrate 21 is smaller than the light reflectivity of the body portion 211 and the light reflectivity of the original layers 2121, and correspondingly, the light transmittance of the modified layers 2122 is also smaller. The illumination of light with the illumination of P exiting after passing through the body portion 211 and/or the original layer 2121 is, for example, in a range of 0.95P to P; and the illumination of the light with the illumination P exiting after passing through the modified layer 2122 is, for example, 0.8P It can be understood that if the modified layer 2122 extends into the functional region AA, it will affect the light extraction effect of the chip structure 10.

For example, the original layers 2121 and the modified layers 2122 are subjected to different stresses.

It can be understood that the body portion 211 of the base substrate 21 is the part of the base substrate 21 that is not affected by the laser, and the modified layers 2122 of the edge portion 212 are the part of the base substrate 21 that is close to the cutting surfaces and undergoes structural changes caused by the laser. The original layers 2121 are also the part that is not affected by the laser during the laser cutting.

For example, the body portion 211 and the original layers 2121 have the same light reflectivity.

The light reflectivity described here refers to the reflectivity of the body portion 211 and original layers 2121 to light of a wavelength in a range of 380 μm to 780 μm.

For example, the body portion 211 and the original layers 2121 are subjected to the same stresses.

In some embodiments, as shown in FIG. 2, the base substrate 21 includes a first surface 21a and a second surface 21b that are opposite and a plurality of side surfaces connecting the first surface 21a and the second surface 21b. The second surface 21b is closer to the chip wafer unit 1 than the first surface 21a. As shown in FIG. 8, the edge portion 212 includes a plurality of sub-portions 212(k) that are respectively arranged corresponding to the plurality of side surfaces of the base substrate 21.

In some examples, the number of modified layers 2122 included in each of the plurality of sub-portions 212(k) is the same.

In some other examples, the number of modified layers 2122 included in each of the plurality of sub-portions 212(k) of the edge portion 212 is not necessarily the same.

It should be noted that, with reference to the above description of the manufacturing method of the chip structure 10, the number of modified layers 2122 included in each sub-portion 212(k) among the plurality of sub-portions 212(k) included in the edge portion 212 is the same as the number of focuses D for the laser cutting.

In some embodiments, with reference to the above description corresponding to the manufacturing method of the chip structure 10, as shown in FIG. 8, the chip structure 10 includes the functional region AA, the functional region AA includes a plurality of light-emitting regions A2, and each light-emitting region A2 is provided therein with at least one light-emitting layer 13. When each light-emitting region A2 includes a plurality of light-emitting layers 13, the plurality of light-emitting layers 13 are connected to each other. The plurality of light-emitting layers 13 in each light-emitting region A2 are, for example, connected in series or in parallel.

For example, the plurality of light-emitting regions A2 may include a light-emitting region of a first color, a light-emitting region of a second color and a light-emitting region of a third color.

For example, the first color is red, the second color is green, and the third color is blue.

For example, the light-emitting layer(s) 13 in the same light-emitting region A2 are configured to emit light of one color of a plurality of colors. The light of the plurality of colors includes, but is not limited to, blue light.

In some examples, the plurality of light-emitting layers 13 are each configured to emit blue light. As shown in FIG. 2, after passing through the color conversion layer 24, the blue light emitted by the light-emitting layer 13 in each light-emitting region A2 maintains blue light and exits, or is converted into red light or green light and exits.

In some examples, light-emitting layers 13 in different light-emitting regions A2 are configured to emit light of the same color.

In this case, the chip wafer unit 1 can emit light of a plurality of colors. For example, the light-emitting layers 13 corresponding to the plurality of light-emitting regions A2 all emit light of different colors. After passing through the color conversion unit 2, the light of a color emitted by the light-emitting layer 13 corresponding to each light-emitting region A2 remains the light of the same color and exits, so that the chip structure 10 can emit light of a plurality of colors.

In some other examples, light-emitting layers 13 in at least two light-emitting regions A2 are configured to emit light of different colors.

In this case, the chip wafer unit 1 can emit light of a single color. For example, the light-emitting layers 13 corresponding to the plurality of light-emitting regions A2 all emit light of the same color. After passing through the color conversion unit 2, the light of a color emitted by the light-emitting layer 13 corresponding to each light-emitting region A2 remains the light of the same color and exits, or is converted to light of another color and exits, so that the chip structure 10 can emit light of a plurality of colors.

In the chip structure 10 provided in some embodiments of the present disclosure, as shown in FIG. 2, the color conversion unit 2 is used to perform color conversion on the light emitted by the chip wafer unit 1. Therefore, the plurality of light-emitting layers 13 of the chip wafer unit 1 can emit light of the same color. For example, the plurality of light-emitting layers 13 are all configured to emit blue light, and the chip structure 10 can still emit light of a plurality of colors.

For example, among the plurality of light-emitting layers 13 included in the chip wafer unit 1, the blue light emitted by the light-emitting layer 13 in a light-emitting region A2 after passing through the color conversion layer 24 maintains the blue light and exits, the blue light emitted by the light-emitting layer 13 in another light-emitting region A2 after passing through the color conversion layer 24 is converted into red light and exits, and the blue light emitted by the light-emitting layer 13 in yet another light-emitting region A2 after passing through the color conversion layer 24 is converted into green light and exits.

In the case where the chip structure 10 is applied to the display apparatus 100, for example, only the chip wafer unit 1 of blue light needs to be produced. Through the color conversion unit 2, the blue light emitted by the chip wafer unit 1 of blue light is kept as blue light for emission, or is converted into light of another color (e.g., red light or green light) for emission. In this way, when manufacturing the chip structure 10, the chip wafer unit 1 can emit light of a single color, and the color of the light emitted by the chip wafer unit 1 is converted by the color conversion unit 2, thereby realizing multi-color light emission of the chip structure 10 and in turn realizing multi-color display of the display device 100.

In some embodiments, the chip wafer unit can emit light of a plurality of colors. In this case, the light-emitting layers in each light-emitting region of the chip structure needs to emit light of different colors. The light-emitting layer is, for example, MQW. It can be understood that, a plurality of MQWs capable of emitting light of different colors are required for forming the light-emitting layers in each light-emitting region of a single chip wafer unit, and the manufacturing process is cumbersome.

In some embodiments of the present disclosure, the chip wafer unit 1 can emit light of a single color, and the color conversion unit 2 performs color conversion on the light emitted by the chip wafer unit 1, thereby realizing multi-color light emission of the chip structure 10. It can be understood that, compared with the case where the chip wafer unit emits light of a plurality of colors, in the manufacturing process of the chip structure 10, the plurality of light-emitting layers 13 are formed using the same MQW, such as InGaN MQW (h-poor (In-poor) gallium nitride multi-quantum well). In this case, the light-emitting layers 13 can emit blue light. After passing through the color conversion layer 24, the blue light emitted by the light-emitting layer(s) 13 in each light-emitting region A2, for example, maintains the blue light and exits, or is converted into red light or green light and exits. In this way, the steps of manufacturing the chip structure 10 are simplified, thereby improving the efficiency of manufacturing the chip structure.

For example, the chip wafer unit 1 and the color conversion unit 2 are bonded together through the connection layer 3, and the bonding effect of the connection layer 3 may be adhesive bonding effect or metallic bonding effect.

For example, the connection layer 3 is, for example, an adhesive layer. The adhesive layer has high shear strength and good bonding stability, which effectively avoids the cracks at the bonding position of the chip wafer unit 1 and the color conversion unit 2. This is only used as an illustration of a possible implementation, and is not intended to limit the specific implementations of the present disclosure.

The following description will be illustrated by taking an example in which the plurality of sub-portions included in the edge portion 212 each include the same number of modified layers 2122.

In some embodiments, as shown in FIG. 9, the edge portion 212 includes N modified layers 2122, N being a positive integer greater than or equal to 1 (N≥2). A modified layer 2122 farthest from the chip wafer unit 1 is a first modified layer 2122(1), and a modified layer 2122 closest to the chip wafer unit 1 is an Nth modified layer 2122(n).

In some examples, a distance h1 between the first modified layer 2122(1) and the first surface 21a of the base substrate 21 is greater than or equal to a distance h2 between any two adjacent modified layers 2122.

For example, the distance h1 between the first modified layer 2122(1) and the first surface 21a of the base substrate 21 is in a range of 15 μm to 35 μm, inclusive.

Further, the distance h1 between the first modified layer 2122(1) and the first surface 21a of the base substrate 21 is, for example, greater than or equal to 20 μm.

In some other examples, a distance h3 between the Nth modified layer 2122(n) and the second surface 21b of the base substrate 21 is greater than or equal to the distance h2 between any two adjacent modified layers 2122.

For example, the distance h3 between the Nth modified layer 2122(n) and the second surface 21b of the base substrate 21 is in a range of 15 μm to 35 μm, inclusive.

Further, the distance h3 between the Nth modified layer 2122(n) and the second surface 21b of the base substrate 21 is greater than or equal to 20 μm.

In yet some other examples, the distance h1 between the first modified layer 2122(1) and the first surface 21a of the base substrate 21 is greater than or equal to the distance h2 between any two adjacent modified layers 2122, and the third distance h3 between the Nth modified layer 2122(n) and the second surface 21b of the base substrate 21 is greater than or equal to the distance h2 between any two adjacent modified layers 2122. In this case, the distance h1 between the first modified layer 2122(1) and the first surface 21a of the base substrate 21 may be the same as or different from the third distance h3 between the Nth modified layer 2122(n) and the second surface 21b of the base substrate 21.

With reference to the above description of the manufacturing method of the chip structure 10, during the manufacturing process of the chip structure 10, the laser is applied to the N focuses D in the base substrate motherboard 21′ in sequence for cutting. In order to avoid the cracks generated in the base substrate motherboard 21 during the laser cutting extend to the surfaces of the base substrate motherboard 21′, the first focus D(1) and the Nth focus D(n) need to have certain distances from the surfaces of the base substrate motherboard 21′ (e.g., the distances d1 and d3 shown in FIG. 9, where d1 and d3 need to be greater than d2).

In this way, in the chip structure 10 formed by the above-mentioned manufacturing method, according to the distance relationship of the N focuses D and the distance relationship between each of both the first focus D(1) and the Nth focus D(n) and the base substrate motherboard 21′, the plurality of original layers 2121 and modified layers 2122 included in the edge portion 212 are formed, where the distance h1 between the first modified layer 2122 and the first surface 21a of the base substrate 21 is greater than or equal to the distance h2 between any two adjacent modified layers 2122, and the distance h3 between the Nth modified layer 2122 and the second surface 21b of the base substrate 21 is greater than or equal to the distance h2 between any two adjacent modified layers 2122.

In this way, it can avoid that the cracks generated during the laser cutting in the manufacturing process of the chip structure 10 extend to the surfaces of the base substrate 21, which causes cracks and other defects on the surfaces of the base substrate 21. Thus, the yield of preparation of the chip structure 10 is guaranteed, and the manufacturing cost of the chip structure 10 is reduced,

In some embodiments, as shown in FIG. 2, the color conversion unit 2 further includes: a color filter layer 22, a defining dam layer 23, a color conversion layer 24 and an encapsulation layer 25. The color filter layer 22 is disposed on a side of the base substrate 21 facing the chip wafer unit 1. The color filter layer 22 includes a black matrix 221 and a plurality of filter portions 222 defined by the black matrix 221. The defining dam layer 23 is disposed on a side of the color filter layer 22 away from the base substrate 21, The defining dam layer 23 includes a plurality of opening regions 231, and each opening region 231 is arranged opposite to a filter portion 222. The color conversion layer 24 is arranged in the same layer as the defining dam layer 23.

Referring to FIGS. 7 and 8, an orthographic projection, on the base substrate 21, of the black matrix 221 is located within a range enclosed by the edge portion 212, and a portion, located in the peripheral region AN, of an orthographic projection of the encapsulation layer 25 on the base substrate 21 overlaps with the edge portion 212.

With reference to the above description of the manufacturing method of the chip structure 10, it can be understood that in the manufacturing process of the chip structure 10, since the cutting surface undergoes structural changes due to the laser when the base substrate motherboard 21′ is cut by the laser, the edge portion 212 is formed. The light reflectivity of the part of the base substrate motherboard 21′ that undergoes structural changes caused by the laser (e.g., the modified layers 2122 of the edge portion 212) is reduced compared with the light reflectivity of the part of the base substrate motherboard 21′ that is not affected by the laser (e.g., the body portion 211 and the original layers 2121 of the edge portion 212). For example, the range of the modified layers 2122 extends into the functional region AA; and when the light emitted by the chip wafer unit 1 passes through the base substrate 21, the reflectivity of a part of the light entering the modified layers 2122 is reduced compared with the reflectivity of a part of the light entering the body portion 211 and the reflectivity of a part of the light entering the original layers 2121, so that the transmittance of the light will be reduced, which results in the reduction of the light extraction efficiency of the chip structure.

Therefore, in order to ensure the light-emitting effect of the chip structure 10, the part of the base substrate 21 undergoing structural changes cannot extend into the functional region AA. That is, it needs to ensure that the modified layers 2122 of the edge portion 212 are located outside the functional region AA (for example, located in the periphery region AN). Therefore, it ensures the light extraction efficiency of the chip structure 10.

It can be understood that, according to the above description of the edge portion 212, the edge portion 212 is a portion of the base substrate 21 that is close to the cutting surfaces and creates modified layers 2122 caused by the laser during the fabricating process using the laser (the laser cuts along one focus D to form one modified layer 2122). Therefore, a width of the modified layer 2122 (e.g., a size e2 shown in FIG. 2) is variable. The width of the modified layer 2122 is less than or equal to a width of the peripheral region AN. The body portion 211 in the base substrate 21 is at least located in the functional region AA, and can extend to the peripheral region AN.

It should be noted that the base substrate 21 is, for example, in a shape of a rectangle. In this case, the base substrate 21 includes four side surfaces and the peripheral area AN in a shape of a Chinese character “ [symbol] ”. The peripheral region AN includes four portions in one-to-one correspondence with the side surfaces. Here, the comparison between the width of the modified layer 2122 and the width of the peripheral region AN is the comparison between a width of a part of the peripheral region AN corresponding to any side surface of the base substrate 21 and a width of the modified layer 2122 in a sub-portion 212(k) of the edge portion 212 located in the part of the peripheral region AN.

In some embodiments, as shown in FIG. 2, the plurality of opening regions 231 include first-type opening regions 2311 and second-type opening regions 2312. The color conversion layer 24 includes color conversion portions 241 disposed in the first-type opening regions 2311 and filling portions 242 disposed in the second-type opening regions 231.

For example, each filter portion 222 is arranged corresponding to at least one light-emitting layer 13. The plurality of filter portions 222 include, for example, first filter portion(s), second filter portion(s), and third filter portion(s). The first filter portion, second filter portion, and third filter portion are each arranged opposite to at least one light-emitting layer 13.

When each light-emitting region A2 includes a plurality of light-emitting layers 13, for example, the plurality of light-emitting layers 13 in each light-emitting region A2 are arranged corresponding to the same filter portion 222; or, the plurality of light-emitting layers 13 in each light-emitting region A2 are arranged corresponding to a plurality of filter portions 222, respectively.

For example, the filter portions 222 are color filters or color films.

In some examples, the first filter portion is a red filter portion, the second filter portion is a green filter portion, and the third filter portion is a blue filter portion.

For example, the color conversion portion 241 is a quantum dot conversion portion or a fluorescent color conversion portion.

In some examples, the quantum dot conversion portion includes a first quantum dot conversion portion and a second quantum dot conversion portion.

In some other examples, the fluorescent color conversion portion includes a first fluorescent color conversion portion or a second fluorescent color conversion portion.

For example, the light-emitting layer emits blue light; and the blue light is converted into red light to exit after passing through the first quantum dot conversion portion or the first fluorescent color conversion portion.

For example, the light-emitting layer emits blue light; and the blue light is converted into green light to exit after passing through the second quantum dot conversion portion or the second fluorescent color conversion portion.

It can be understood that the color conversion portion 241 can also be made of other materials, as long as it can achieve the color conversion function. This is only used as an illustration of a possible implementation, and is not intended to limit the specific implementations of the present disclosure.

For example, the material of the filling portion 242 includes, but is not limited to, scattering particles or transparent glue.

For example, the light-emitting layer 13 in the light-emitting region A2 corresponding to the filling portion 242 emits blue light, and a part of the chip structure 10 corresponding to the same light-emitting region A2 also emits blue light. Therefore, the light emitted by the light-emitting layer 13 in this part does not need to undergo color conversion. It can be understood that the filling portion 242 is configured to fill an opening region 231 corresponding thereto, resulting in a flat filling of the opening region 231. The material of the filling portion 242 should have good light transmittance to ensure the light-emitting effect of the chip structure 10.

It can be understood that the filling portion 242 can also be made of other materials, as long as it can achieve the filling effect of the corresponding opening region 231, has good light transmittance, and does not change the color of the light when the light passes through the filling portion 242. This is only used as an illustration of a possible implementation, and is not intended to limit the specific implementations of the present disclosure.

In some embodiments, as shown in FIG. 2, a distance between a border of the black matrix 221 and the side surface of the base substrate 21 is e1, and a size of the modified layer 2122 in a direction that is parallel to the first surface 21a of the base substrate 21 and perpendicular to the side surface of the base substrate 21 is e2, and e2 is less than or equal to e1 (e2≤e1).

It can be understood that the distance e1 in the comparison refers to a distance between any side surface of the base substrate 21 and a border of the black matrix 221 that is proximate to the any side surface of the base substrate 21.

For example, as shown in FIG. 2, the distance e1 between the border of the black matrix 221 and the side surface of the base substrate 21 is in a range of 10 μm to 30 μm, inclusive.

For example, as shown in FIG. 2, the size of the modified layer 2122 in the direction parallel to the first surface 21a of the base substrate 21 and perpendicular to the side surface of the base substrate 21 is e2, which is in a range of 5 μm to 10 μm, inclusive.

For example, the black matrix 221 is located in the functional region AA.

Referring to FIG. 2 and the above description of the manufacturing method of the chip structure 10, the distance e1 between the border of the black matrix 221 and a border of the base substrate 21 is formed after the laser cuts the base substrate motherboard 21′ along the cutting lane Q. During the cutting of the base substrate motherboard 21′, a plane that the laser cutting path is located in and is perpendicular to the first surface 21′a of the base substrate motherboard 21′ coincides or substantially coincides with a plane that the symmetry axis of the cutting lane Q is located in and is perpendicular to the first surface 21′a of the base substrate motherboard 21′. Therefore, in the plurality of chip structures 10 that are finally formed, the range of the distance e1 between the border of the black matrix 221 and the border of the base substrate 21 is approximately a range of half of the distance d4 shown in FIG. 8.

Using the manufacturing method described above, in the coupling structure C including a plurality of chip structures 10, the width of the cutting lane Q (e.g., the size d4 shown in FIG. 8) is in a range of 20 μm to 50 μm, inclusive. The cutting path may not completely equally divide the cutting lane Q into two opposite parts during the laser cutting.

Therefore, in the chip structure 10, the range of the distance e1 between the border of the black matrix 221 and the border of the base substrate 21 is greater than

$$\frac{{d}_{4}}{2} .$$

During the manufacturing process, the distance between the focus D and the surface (the first surface 21′a and/or the second surface 21′b) of the base substrate motherboard 21′ is controlled, which is reflected in the width of the peripheral region AN of the formed chip structure 10. When the laser is cutting the substrate motherboard 21′, the range of the heat-affected zone of the laser cannot cover surface structures of the chip structure 10 (e.g., the structures in the functional region AA). For example, the encapsulation layer 25 is 20 μm away from a cutting line, and when the range of the heat-affected zone during the laser cutting exceeds 20 μm, the encapsulation layer 25 will be damaged, causing the color conversion layer 24 (e.g., the color conversion portion 241) covered by the encapsulation layer 25 to fail. As a result, the chip structure 10 cannot emit light normally.

With reference to the above description of the manufacturing method of the chip structure 10, the cutting line described here is a cutting path of the laser cutting along a path of the focus D that is parallel to the first surface 21′a of the base substrate motherboard 21′ and located in the cutting lane Q.

The foregoing descriptions are merely specific implementation manners of the present disclosure, but the protection scope of the present disclosure is not limited thereto, any changes or replacements that a person skilled in the art could conceive of within the technical scope of the present disclosure shall be included in the protection scope of the present disclosure. Therefore, the protection scope of the present disclosure shall be subject to the protection scope of the claims.

1. A chip structure, comprising: a chip wafer unit and a color conversion unit disposed on a light exit side of the chip wafer unit, wherein
the color conversion unit includes a base substrate; the base substrate includes a body portion and an edge portion surrounding the body portion; the edge portion includes original layers and modified layers alternately arranged along a first direction; in the edge portion, layers located on outermost two sides in the first direction are both original layers; and a light reflectivity of the original layers and a light reflectivity of the modified layers are different;
the first direction being perpendicular to a surface of the base substrate away from the chip wafer unit.

2. The chip structure according to claim 1, wherein the body portion and the original layers have the same light reflectivity.

3. The chip structure according to claim 1 wherein the base substrate includes a first surface and a second surface opposite to each other in the first direction, and a plurality of side surfaces connecting the first surface and the second surface; the second surface is closer to the chip wafer unit than the first surface, and the edge portion includes a plurality of sub-portions that are respectively arranged corresponding to the plurality of side surfaces;
a number of modified layers included in each of the plurality of sub-portions is the same; or
the number of modified layers included in each of the plurality of sub-portions is not necessarily the same.

4. The chip structure according to claim 3, wherein at least one sub-portion among the plurality of sub-portions includes N modified layers, N is a positive integer, and N >2;
a modified layer farthest from the chip wafer unit is a first modified layer, and a distance between the first modified layer and the first surface is greater than a distance between any two adjacent modified layers; and/or
a modified layer closest to the chip wafer unit is an Nth modified layer, and a distance between the Nth modified layer and the second surface is greater than the distance between any two adjacent modified layers.

5. The chip structure according to claim 4, wherein the distance between the first modified layer and the first surface is in a range of 15 μm to 35 μm, inclusive; and/or
the distance between the Nth modified layer and the second surface is in a range of 15 μm to 35 μm, inclusive.

6. The chip structure according to claim 4, wherein the distance between the first modified layer and the first surface is greater than or equal to 20 μm; and/or
the distance between the Nth modified layer and the second surface is greater than or equal to 20 μm.

7. The chip structure according to claim 1, wherein the color conversion unit further includes:
a color filter layer disposed on a side of the base substrate facing the chip wafer unit and including a black matrix and a plurality of filter portions defined by the black matrix, an orthographic projection of the black matrix on the base substrate being located within a range enclosed by the edge portion;
a defining dam layer disposed on a side of the color filter layer away from the base substrate and including a plurality of opening regions, the plurality of opening regions being in one-to-one correspondence with the plurality of filter portions; and
a color conversion layer arranged in the same layer as the defining dam layer.

8. The chip structure according to claim 7, wherein the plurality of opening regions include a first-type opening region and a second-type opening region;
the color conversion layer includes a color conversion portion and a filling portion; the color conversion portion is arranged in the first-type opening region, and the filling portion is arranged in the second-type opening region;
the color conversion portion includes a quantum dot conversion portion or a fluorescent color conversion portion; and
the filling portion includes a scattering particle portion or transparent glue.

9. The chip structure according to claim 7, wherein the base substrate includes a functional region and a peripheral region surrounding the functional region, and an orthographic projection of the chip wafer unit on the base substrate is located in the functional region; the body portion is located at least in the functional region, and the edge portion is located in the peripheral region;
the color conversion unit further includes:
an encapsulation layer covering the color filter layer, wherein a portion, located in the peripheral region, of an orthographic projection of the encapsulation layer on the base substrate overlaps with the edge portion.

10. The chip structure according to claim 7, wherein a distance between a border of the black matrix and a side surface of the base substrate is e1, a size of a modified layer in a direction that is parallel to the first surface and perpendicular to the side surface is e2, and e2≤e1.

11. The chip structure according to claim 10, wherein the size e2 of the modified layer in the direction that is parallel to the first surface and perpendicular to the side surface is in a range of 5 μm to 10 μm, inclusive.

12. The chip structure according to claim 10, wherein the distance e1 between the border of the black matrix and the side surface is in a range of 10 μm to 30 μm, inclusive.

13. A display apparatus, comprising a driving substrate and a plurality of chip structures according to claim 1;
the driving substrate being coupled to the plurality of chip structures.

14. A method for manufacturing a chip structure, comprising:
forming an initial wafer, the initial wafer including a plurality of chip wafer units;
forming a color conversion substrate, wherein the color conversion substrate includes a base substrate motherboard and a plurality of color conversion structures disposed on the base substrate motherboard, and each color conversion structure and a portion of the base substrate motherboard corresponding thereto constitute a color conversion unit;
coupling the color conversion substrate to the initial wafer to obtain a coupling structure, each chip wafer unit being arranged opposite to one color conversion unit; and
sequentially applying laser to a plurality of focuses inside the base substrate motherboard for cutting, wherein the plurality of focuses are arranged sequentially in a first direction, the first direction being perpendicular to a surface of the base substrate motherboard away from the plurality of color conversion structures; the base substrate motherboard is cut to form a plurality of base substrates, each base substrate includes a body portion and an edge portion surrounding the body portion, the edge portion includes original layers and modified layers alternately arranged along the first direction, and layers located on outermost two sides in the first direction are both original layers.

15. The method according to claim 14, wherein in the step of sequentially applying the laser to the plurality of focuses inside the base substrate motherboard for cutting, the base substrate motherboard is cut from a side of the color conversion substrate of the coupling structure away from the initial wafer.

16. The method according to claim 14, wherein the base substrate motherboard includes a plurality of cutting lanes, and the laser cuts along the cutting lanes;
when the laser cuts each of the cutting lanes, a number of focuses to which the laser is applied is the same or not necessarily the same.

17. The method according to claim 14, wherein a number of the plurality of focuses is N, N is a positive integer, and N≥2; a focus farthest from the initial wafer is a first focus, and a focus closest to the initial wafer is an Nth focus; a surface of the base substrate motherboard away from the initial wafer is a first surface, and a surface of the base substrate motherboard close to the initial wafer is a second surface;
a distance between the first focus and the first surface is greater than or equal to a distance between any two adjacent focuses; and/or
a distance between the Nth focus and the second surface is greater than or equal to the distance between any two adjacent focuses.

18. The method according to claim 17, wherein the distance between the first focus and the first surface is in a range of 15 μm to 35 μm, inclusive; and/or
the distance between the Nth focus and the second surface is in a range of 15 μm to 35 μm, inclusive.

19. The method according to claim 14, wherein a distance between any two adjacent chip structures is in a range of 20 μm to 50 μm, inclusive.

20. The chip structure according to claim 8, wherein the base substrate includes a functional region and a peripheral region surrounding the functional region, and an orthographic projection of the chip wafer unit on the base substrate is located in the functional region; the body portion is located at least in the functional region, and the edge portion is located in the peripheral region; and
the color conversion unit further includes an encapsulation layer covering the color filter layer, wherein a portion, located in the peripheral region, of an orthographic projection of the encapsulation layer on the base substrate overlaps with the edge portion.
